(19) United States
(12) Patent Application Publication
(10) Pub. No.: US 2012/0091339 A1
(43) Pub. Date: Apr. 19, 2012

(54) CHARGED-PARTICLE MICROSCOPE DEVICE, AND METHOD OF CONTROLLING CHARGED-PARTICLE BEAMS

(75) Inventors: Yusuke Ominami, Hitachinaka (JP); Hiroshi Miyai, Hitachi (JP); Yasuhiro Gunji, Hitachiota (JP)

(73) Assignee: HITACHI HIGH-TECHNOLOGIES CORPORATION, Minato-ku, Tokyo (JP)

(21) Appl. No.: 13/378,561

(22) PCT Filed: Jun. 15, 2010
(86) PCT No.: PCT/JP2010/060082

§ 371 Date: Dec. 15, 2011

(30) Foreign Application Priority Data
Jun. 16, 2009 (JP) 2009-142834

(51) Int. Cl. H01J 37/26

(52) U.S. Cl. 250/307; 250/311

(57) ABSTRACT

A charged-particle microscope device and a method of controlling charged-particle beams are provided, which are capable of signal detection at the time when the charged state of an observation sample or a defect portion becomes optimum. Charge accumulation-waiting time T from an initial irradiation with an electron beam 21 for enhancing charge accumulation on an observation sample 100 until a next irradiation with the electron beam 21 for sample observation is set depending on the state of the observation sample 100 or a defect portion 112 generated on the observation sample 100. The irradiation with the electron beam 21 for enhancing charge accumulation and the irradiation with the electron beam 21 for sample observation are performed on the observation sample 100 on the basis of the charge accumulation-waiting time T.

### TECHNICAL FIELD

The present invention relates to a technology of controlling a charged state and an observation state of a sample by using a charged-particle microscope device.

### BACKGROUND ART

Semiconductor devices such as memories and microcomputers used for computers and the like are manufactured by repeatedly performing processes of transferring patterns of circuits or the like formed in photomasks by exposing, lithographing, and etching processes.

In the process of manufacturing semiconductor devices, the manufacturing yield of semiconductor devices is greatly influenced by the quality of results from lithographing, etching, and other processes and by the presence of a defect, such as occurrence of a foreign matter. Accordingly, in order to detect occurrences of an abnormality or a defect at an early phase or in advance, a pattern on a semiconductor wafer is inspected at the end of each manufacturing step using a scanning electron microscope (hereinafter also referred to as an SEM)-type visual inspection device. Hereinafter, an inspection method using such an SEM is referred to as an electron beam inspection method.

The electron beam inspection method obtains a higher-resolution observation image than optical visual inspection or laser inspection, and accordingly is capable of detecting a minute foreign matter and defect on a fine circuit pattern. In addition, the electron beam inspection method can form voltage contrast, resulting from reflection of a potential difference on the surface in the efficiency of emitting secondary electrons, due to charge accumulation by electron beam irradiation. Accordingly, electrical continuity or non-continuity of a circuit pattern formed on the surface of a semiconductor wafer or a lower layer therein as well as an electrical defect such as a short circuit in an interconnection or a transistor can also be detected with observation images thereof.

Meanwhile, in the electron beam inspection method, an inspection result is greatly affected due to charge accumulation. Thus, when secondary electrons or reflected electrons generated from an observation sample by simply scanning with an electron beam are detected and converted into a signal as in an ordinal scanning electron microscope, the obtained result brings about a problem that only an insufficient amount of charges are accumulated on the observation sample at the time of obtaining an observation image.

Against this background, methods of actively controlling a charged state of an observation sample have been proposed to address such a problem.

For example, Patent Document 1 describes a method of enhancing charge accumulation on an observation sample using an electron gun for enhancing charge accumulation, the electron gun provided in addition to an electron gun for electron microscope.

However, in practice, such a method which just enhances only the state of charge accumulation of an observation sample is insufficient for controlling the charged state of the observation sample. This is because a period for forming an optimum electric-potential distribution or charged state for observation varies depending on conditions of an observation sample or a defect portion. Accordingly, the observation can be performed in many cases only after waiting the period elapses for forming an optimum electric-potential distribution or charged state from the beginning of enhancing charge accumulation on an observation sample or a defect portion by electron beam irradiation.

Specifically, assuming that an observation sample or defect portion to be detected is a capacitance component in an equivalent circuit, the surface potential state of the observation sample or defect portion to be detected is determined by the capacitance component. The aforementioned waiting time is determined by a period from when charges begin accumulating on the capacitance component to when the charge accumulation reaches the maximum. In other words, the period from a moment when charges begin accumulating on the observation sample or defect portion to be detected to a moment for observation is an important factor in determining the aforementioned optimum electric-potential distribution or charged state.

In this regard, Patent Documents 2 and 3 describe inspection methods in which an observation sample including a plug having a pn junction is irradiated with an electron beam multiple times at irradiation intervals shorter than the charge relaxation period of a plug having a normal pn junction to thereby make charge accumulation on the plug having the normal pn junction reach a saturated state. Thus, a normal portion and a leakage-generated portion are made to have a difference in charge accumulation, and are distinguished from each other through observation of the difference in charge accumulation as voltage contrast, i.e., the difference in brightness. Moreover, this interval of multiple electron beam irradiations is described such that the electron beam current, the electron beam irradiation time, and the interval time of electron beam irradiation are made variable and controlled independently. Further, it is stated that the settings thereof are made by inputting individual inspection parameters, or that by selecting a desired inspection condition file from combinations of various inspection parameters which are organized as inspection condition files in a database in advance.

### PRIOR ART DOCUMENTS

### Patent Documents

Patent Document 1: Japanese Patent Application Publication No. Hei 10-294345
Patent Document 2: Japanese Patent Application Publication No. 2002-009121
Patent Document 3: Japanese Patent Application Publication No. 2004-031379

### SUMMARY OF THE INVENTION

### Problems to be Solved by the Invention

In the electron beam inspection method as described above, inspection of an observation sample or defect portion to be detected can be performed only after waiting for charges to be optimally accumulated on the observation sample or defect portion to be detected by irradiation of charged-particle beams including electron beams. On the other hand, the inspection device has to achieve as high inspection throughput as possible, by scanning with electron beams for irradiating an observation sample and detecting a signal such as secondary electrons generated from the observation sample at high speeds.

However, waiting for this observation sample to turn into an optimum charged state is in a trade-off relationship with increasing the inspection throughput. Hence, a technology and a method to control charge accumulation are needed to attain an optimum charged state of an observation sample and the maximum throughput.

In this respect, in the inspection methods described in Patent Documents 2 and 3, even though the electron beam current, the electron beam irradiation time, and the interval time of electron beam irradiation are variable, the interval time of electron beam irradiation among them is set to merely to bring charge accumulation on a plug having a normal pn junction (the plug corresponds to an observation sample) into the saturated state by performing multiple times of electron beam irradiations. In other words, in the inspection method described in Patent Documents 2 and 3, the interval time of the electron beam irradiation is also set to bring the charge accumulation on an observation sample into the saturated state by performing multiple electron beam irradiations, but is not intended to set a period from a moment when charges begin accumulating on an observation sample or defect portion to be detected to a moment for observation.

Further, the inspection methods described in Patent Documents 2 and 3 still requires a lot of work for the settings by inputting individual inspection parameters such as interval time or by selecting an inspection condition file from predetermined combinations of inspection parameters. This is because a period for forming an optimum electric-potential distribution or charged state for observation varies due to a small difference in conditions of an observation sample or defect portion as described above.

The present invention has been made in view of such points. An object of the present invention is to provide a charged-particle microscope device and a method of controlling charged-particle beams both including a technology of controlling charge accumulation and controlling electron beams, which are capable of signal detection at the time when the charged state of an observation sample or a defect portion becomes optimum.

### Means for Solving the Problems

A charged-particle microscope device and a method of controlling charged-particle beams according to the present invention are characterized by having a function of irradiating any inspection region of an observation sample with charged-particle beams at least twice or more times, and a function of precisely and speedily setting a time lag between an initial ((n−1)th (note that n>2)) charged-particle beam irradiation for enhancing charge accumulation and a next (nth) charged-particle beam irradiation for sample observation (or for capturing an image), depending on a state of the observation sample or a defect portion.

In addition, the time lag between the initial charged-particle beam irradiation for enhancing charge accumulation and the next charged-particle beam irradiation for sample observation is adjusted by a controlling electromagnetic lens for charged-particle beam irradiation at least twice or more times and a control system of the controlling electromagnetic lens. The time lag can be easily set based on an inspection result of adjusted time lags for inspection sites that are further restricted regions in any observation region of an observation sample.

Moreover, the time lag between the initial charged-particle beam irradiation for enhancing charge accumulation and the next irradiation for sample observation can be adjusted also by providing two or more charged-particle beam generators.

### EFFECTS OF THE INVENTION

According to the present invention, an optimum charge accumulation-waiting time from an initial charged-particle beam irradiation for enhancing charge accumulation until a next charged-particle beam irradiation for sample observation can be precisely, speedily, and easily set. This enables detection of a signal such as a secondary electron generated from an observation sample at the time when the charged state of the observation sample becomes optimum. Thus, the accuracy of the inspection result can be improved, and the inspection throughput can also be increased.

### BRIEF DESCRIPTION OF THE DRAWINGS

FIG. 1 is a cross-sectional view of a semiconductor wafer, as one example of an observation sample, including a normal portion and a defect portion.

FIG. 2 is a circuit diagram of an equivalent circuit of each of a normal portion and a defect portion of a via when each portion is irradiated with a charged-particle beam.

FIG. 3 is a graph showing a relationship between the passage of time and a voltage in a case where a pulse current having a current pulse width of 10 [nsec] is inputted to each of the normal portion and the defect portion.

FIG. 4 is a configuration diagram of an SEM-type visual inspection device according to one embodiment of the present invention.

FIG. 5 is an explanatory drawing illustrating a manner that arbitrary number of irradiation positions aligned in a direction of one scanning line with the electron beam are sequentially irradiated with an electron beam, and the electron beam then returns to an original irradiation position.

FIG. 6 is an explanatory drawing illustrating a manner that irradiation positions of a maximum number of pixels included in one scanning line with the electron beam are sequentially irradiated with an electron beam for each of multiple scanning lines, and the electron beam then returns to an irradiation-starting position on an original scanning line.

FIG. 7 is a view showing one example of an inspection parameter-input screen as one mode of an input monitor screen in the SEM-type visual inspection device.

FIG. 8 is a view showing one example of an inspection starting screen as one mode of the input monitor screen in the SEM-type visual inspection device.

FIG. 9 is a flowchart of an inspection condition-setting process executed when the SEM-type visual inspection device conducts an actual inspection.

FIG. 10 is a table for explaining stored data accumulatively stored in a storage part as a result of trial inspections repeated several times while inspection conditions are changed.

FIG. 11 is an example of a result of trial inspections repeated several times while inspection conditions are changed, the result displayed in the form of a graph in an inspection result-display window based on a relationship between a charge accumulation-waiting time T and the number of defects.

FIG. 12 is an example of the result of the trial inspections repeated several times while inspection conditions are changed, the result displayed in the form of a graph in the inspection result-display window based on a relationship between a sampling frequency f and the number of defects.

FIG. 13 is a configuration diagram of one example of an SEM-type visual inspection device according to another embodiment of the present invention, the SEM-type visual inspection device including at least two or more electron guns for electron beam irradiation.

FIG. 14 is a configuration diagram of another example of the SEM-type visual inspection device including at least two or more electron guns for electron beam irradiation.

FIG. 15 is a view showing one example of an inspection parameter-input screen as one mode of an input monitor screen in the SEM-type visual inspection device including the at least two or more electron guns.

FIG. 16 shows a modification example of the inspection parameter-input screen shown in FIG. 15.

### MODES FOR CARRYING OUT THE INVENTION

Hereinafter, embodiments of a charged-particle microscope device and a method of controlling charged-particle beams of the present invention will be described based on the drawings. Note that the present invention is applicable also to general charged-particle microscope devices such as electron microscope devices and ion microscopes; nevertheless, in the following description, the embodiments will be specifically described taking an example where the present invention is applied to a visual inspection device installed in a manufacturing step of semiconductor wafers. Additionally, in the visual inspection device in the embodiments, the charged-particle microscope device for observing an image is supposed to be an SEM. Controlling charge accumulation-waiting time to be described later is applicable also to a visual inspection device including an electron emission microscope (EEM, electron emission microscopy) for surface irradiation.

Principle

Now, a basic principle for identifying a defect on a semiconductor wafer with the SEM-type visual inspection device according to the present embodiments will be described first.

In order to emphasize a difference in electrical properties of an observation sample, the SEM-type visual inspection device according to the present embodiment has a function of controlling or setting charged-particle beam irradiation time and time between an initial (for example, first) charged-particle beam irradiation and a next (for example, second) charged-particle beam irradiation.

Hereinafter, the basic principle for identifying a defect with the SEM-type visual inspection device of the present embodiments will be described taking an example, for convenience of description, where the observation sample is a semiconductor wafer in which multiple vertical interconnections (hereinafter referred to as vias) are formed.

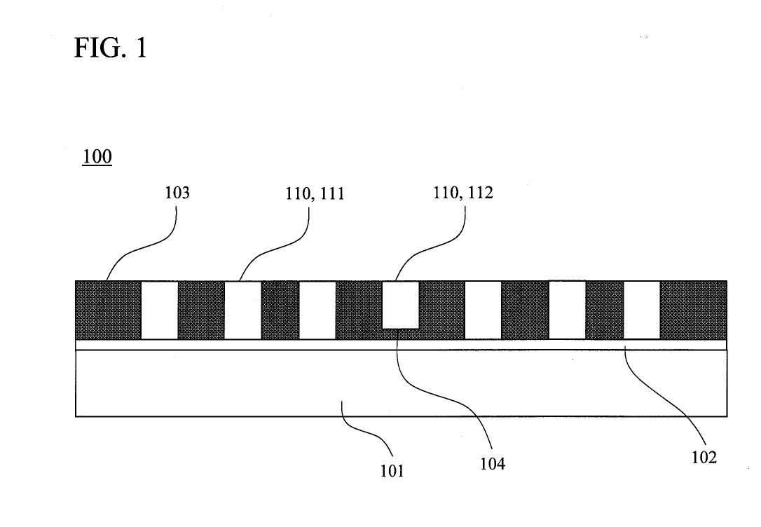

FIG. 1 is a cross-sectional view of the semiconductor wafer, as one example of the observation sample, including a normal portion and a defect portion.

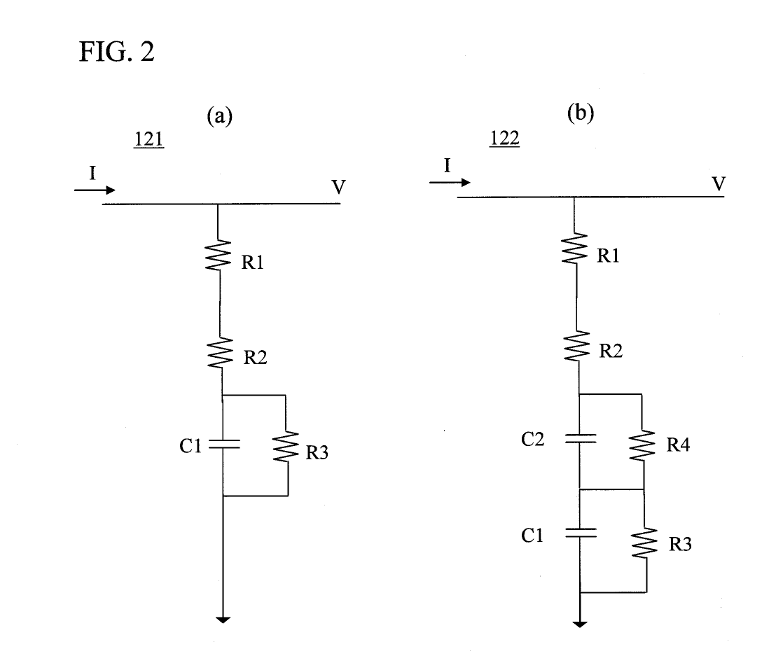

A semiconductor wafer 100 illustrated as an observation sample has a configuration in which multiple vias 110 are formed at intervals apart from each other in an insulating film layer 103 formed on a metal film 102 on the surface of a substrate 101. Each of the vias 110 is a vertical interconnection having one end exposed from the surface of the wafer and the other end extending in a film thickness direction of the insulating film layer 103 in such a manner as to contact the metal film 102. Moreover, the multiple vias 110 include: a normal portion 111 whose via hole penetrates the insulating film layer 103, so that a bottom portion (the other end) of the via 110 contacts the metal film 102; and a defect portion 112 whose via hole does not penetrate the insulating film layer 103, so that a bottom portion (the other end) of the via 110 does not contact the metal film 102 with an insulating film portion (defect portion) 104 interposed between the via hole and the metal film 102. FIG. 2 shows equivalent circuits in a case where such a normal portion 111 and a defect portion 112 of the vias 110 are each irradiated with an electron beam, that is, a charged-particle beam.

FIG. 2 is an equivalent circuit of each of the normal portion and the defect portion of the vias when each portion is irradiated with a charged-particle beam. Part (a) of FIG. 2 shows the equivalent circuit of the normal portion of the via, and Part (b) of FIG. 2 shows the equivalent circuit of the defect portion of the via.

In the normal portion 111, the via 110 is continuous with the metal film 102. Accordingly, a via interconnection resistance R1 and a metal film resistance R2 can represent a portion of the equivalent circuit between the via and the metal film in the normal portion 111.

In contrast, in the defect portion 112, the metal film 102 is not continuous with the via 110. Accordingly, a capacitance component C2 and a resistance component R4 of the insulating film portion (defect portion) 104 in addition to the via interconnection resistance R1 and the metal film resistance R2 can represent a portion of the equivalent circuit between the via and the metal film in the defect portion 112.

Incidentally, herein; a metal-metal interface resistance at a contact portion between the via 110 and the metal film 102 in the normal portion 111 and a metal-insulating film interface resistance at a contact portion between the via 110 or the metal film 102 and the insulating film portion 104 in the defect portion 112 are omitted for convenience to facilitate understanding in the above description of the equivalent circuit. Additionally, the defect portion 112 and the normal portion 111 of the vias 110 differ from each other in the resistance value of the via interconnection resistance R1 only by the difference in the resistance length that corresponds to the presence or absence of the thickness of the insulating film portion 104. Nevertheless, the difference is rather small in comparison with the value of the resistance component R4 of the insulating film portion (defect portion) 104. Accordingly, both of the normal portion 111 and the defect portion 112 are shown to have the same value of the interconnection resistance R1 in the via 110 for convenience.

Besides, in any case where the via 110 is either the normal portion 111 or the defect portion 112, the semiconductor wafer 100 having these vias 110 formed is irradiated with an electron beam, while being held on a sample stage 7 of an SEM-type visual inspection device 1 to be described later. For this reason, the metal film 102 of the semiconductor wafer 100 held on the sample stage 7 is electrically in contact with the sample stage 7 with the substrate 101 therebetween. Thereby, a portion between the sample stage 7 and the metal film 102 of the semiconductor wafer 100 can be represented by an equivalent circuit which has a configuration including a resistance component R3 and a capacitance component C1 of the substrate 101. As a result, when irradiated with a charged-particle beam, equivalent circuits 121, 122 respectively of the normal portion 111 and the defect portion 112 of the vias 110 are represented as shown in Parts (a) and (b) of FIG. 2.

Thus, a potential V at the wafer surface of each of the normal portion 111 and the defect portion 112 of the vias 110 in the semiconductor wafer 100 can be represented by a circuit formula of formulas (1) and (2) where R₁ is a resistance value of the via interconnection resistance R1, R₂ is a resistance value of the metal film resistance R2, R₃ is a resistance value of the resistance component between the wafer and the stage, R₄ is a resistance component of the insulating film portion 104 that is a defect portion, C1 is a capacitance component between the wafer and the stage, C2 is a capacitance component of the insulating film portion 104 that is a defect portion, and I is an input current by electron beam irradiation.

$$\begin{matrix} [ Mathematical formula 1 ] & \\ Normal portion \text{:} V = ( {R}_{1} + {R}_{2} + \frac{{R}_{3}}{1 + jϖ {C}_{1} {R}_{3}} ) \times I & ( 1 ) \\ [ Mathematical formula 2 ] & \\ Defect portion \text{:} V = ( {R}_{1} + {R}_{2} + \frac{{R}_{3}}{1 + jϖ {C}_{1} {R}_{3}} + \frac{{R}_{4}}{1 + jϖ {C}_{2} {R}_{4}} ) \times I & ( 2 )\end{matrix}$$

Note that in the above formulas, j is an imaginary number, and ω is an angular frequency of the input current I.

In this respect, when the two formulas are compared with each other, the potential V at the wafer surface of the defect portion 112 represented by the formula (2) has an impedance component (R₄/(1+jωC₂R₄)) of the defect portion in the fourth term unlike the potential V at the wafer surface of the normal portion 111 represented by the formula (1). Accordingly, by comparing a potential V at each portion of the wafer surface, the normal portion 111 and the defect portion 112 can be distinguished from each other.

Meanwhile, since the SEM continuously perform scanning with electron beams, it can be said that the input current I is rapidly inputted to the normal portion 111 or the defect portion 112 in the semiconductor wafer 100.

As a result, a current pulse corresponding to the input current I is applied to the normal portion 111 or the defect portion 112.

Here, consider a case, for example, where a current of 50 [nA] is inputted to the normal portion 111 and the defect portion 112 only for 10 [nsec].

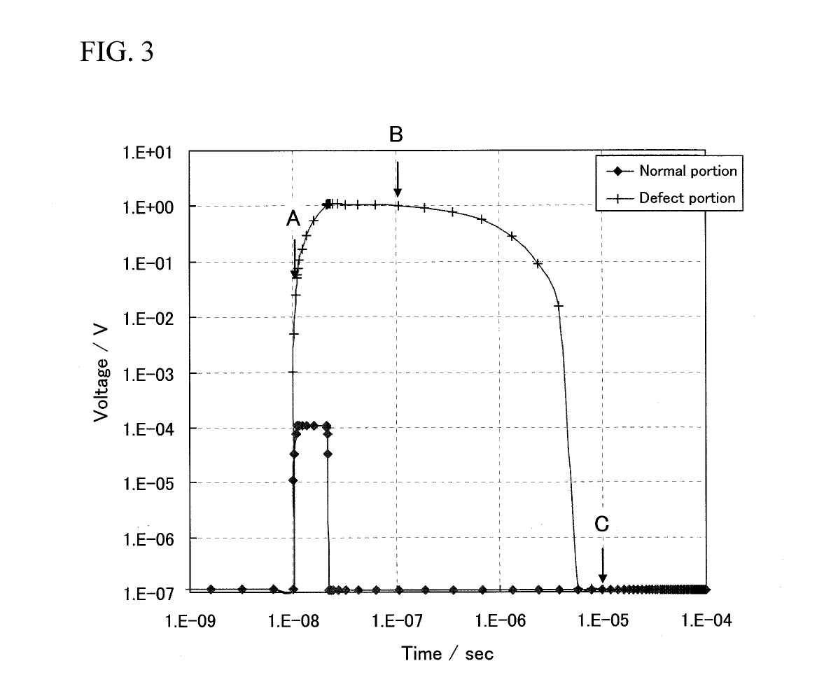

In this event, assume that R₁ above is 100 [ω], R₂ is 100 [ω], R₃ is 1000 [Mω], R₄ is 10 [Gω], C1 is 1 [pF], and C2 is 1 [fF] (= 1/1000 [pF]), the potential V at the wafer surface of each of the normal portion 111 and the defect portion 112 exhibits responses as shown in FIG. 3 to scanning with electron beams.

FIG. 3 is a graph showing a relationship between the passage of time and a voltage in a case where a pulse current having a current pulse width of 10 [nsec] is inputted to each of the normal portion and the defect portion.

At the normal portion 111, only during the current inputting time, that is, approximately 10 [nsec] corresponding to the current pulse width, the wafer surface of the normal portion 111 keeps a voltage around 0.1 [mV]. Meanwhile, at the defect portion 112, during the initial 10 [nsec] corresponding to the current inputting time from the current inputting start time, the potential V at the wafer surface of the defect portion 112 rises to around 1 [V] that is the maximum value, and then continues to fall, over approximately 10 [used], to around 0 [V] that is a value before the current is inputted.

In such a case, if a voltage signal is to be detected from the wafer surface of each of the normal portion 111 and the defect portion 112 only focusing at a moment of electron beam irradiation, the signal is detected at a point A shown in the graph. However, the point A is rising time when a change in the voltage signal over time is abrupt for both the normal portion 111 and the defect portion 112. Thus, there is a possibility that the potential at the wafer surface of the defect portion 112 does not sufficiently rise in comparison with the potential at the wafer surface of the normal portion 111 by a slight difference in time so that the two may not be compared or distinguished from each other.

Moreover, at a point C shown in the graph, charges accumulated in the capacitance components C1, C2 of the defect portion 112 are emitted, and the potential V at the wafer surface of the defect portion 112 is also around 0 [V] which is difficult to distinguish from the potential V at the wafer surface of normal portion 111.

For this reason, to distinguish the normal portion 111 from the defect portion 112, it is important to detect a difference ΔV in potential at the wafer surface between the normal portion 111 and the defect portion 112. Accordingly, a signal for the potential at the wafer surface of each of the normal portion 111 and the defect portion 112 is desirably detected around a point B shown in the graph where the difference ΔV in potential at the surface between the normal portion 111 and the defect portion 112 is the largest.

From such a simple simulation result also, it can be understood that time from an initial (for example, first) electron beam irradiation for enhancing charge accumulation to a next (for example, second) irradiation for sample observation (hereinafter, the period is referred to as charge accumulation-waiting time T) is very important in order to distinguish the normal portion 111 from the defect portion 112.

The values of the circuit components of the equivalent circuits 121, 122 of the normal portion 111 and the defect portion 112 shown in FIG. 2 differ from actual values, depending on the wafer state, defect state, measurement conditions, and the like. Thus, if, for example, the resistance value or the capacitance value of a corresponding circuit component varies, the rising period and the falling period of the wafer surface potential V of each of the normal portion 111 and the defect portion 112 are changed. Nevertheless, even if the values of the circuit components of the equivalent circuits 121, 122 of the normal portion 111 and the defect portion 112 differ from the actual values according to the wafer state, defect state, measurement conditions, and the like, the charge accumulation-waiting time T is still an important parameter in order to observe the normal portion 111 or the defect portion 112 at an optimum surface potential V.

### EMBODIMENTS

Next, description will be given of an SEM-type visual inspection device of the present embodiments and a method of controlling charged-particle beams thereof based on the above-described basic principle for identifying a defect of a semiconductor wafer.

### First Embodiment

### Configuration

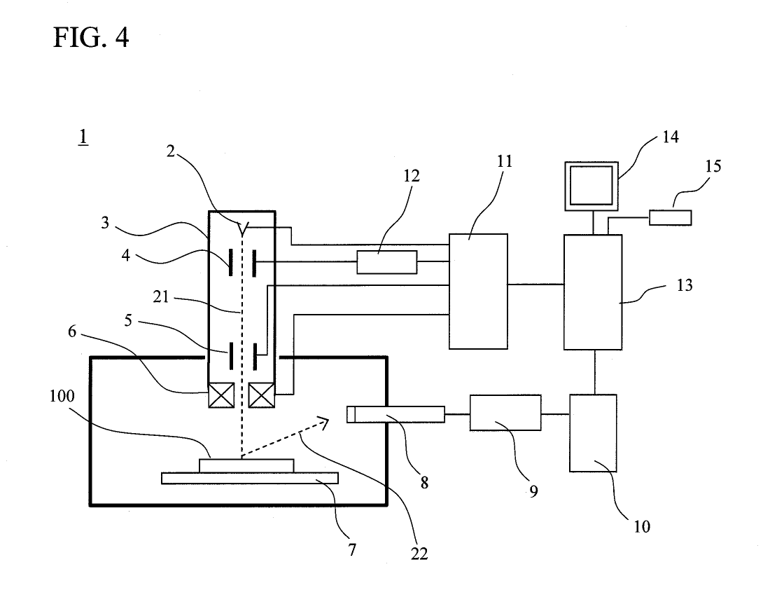

FIG. 4 is a configuration diagram of an SEM-type visual inspection device according to a first embodiment of the present invention.

An SEM-type visual inspection device 1 according to the present embodiment includes an electron gun 3 having an electron source 2, a deflector 4, a blanking electrode 5, an objective lens 6, a sample stage 7, a detector 8, a detection controller 9, an image processor 10, a lens controller 11, a deflector controller 12, a computer 13, a monitor 14, and an input instrument 15.

The electron gun 3 accelerates electrons (charges particles) generated by the electron source 2, and generates an electron beam 21 (primary electron beam 21) to irradiate a semiconductor wafer 100 that is the observation sample 100.

The deflector 4 deflects the electron beam 21 on the basis of a deflection signal supplied from the deflector controller 12, and two-dimensionally scans the observation sample 100 with the electron beam 21.

The blanking electrode 5 deflects the electron beam 21 according to a blanking signal supplied from the lens controller 11 in such a manner that the observation sample 100 is not irradiated with the electron beam 21, and turns ON/OFF the irradiation with the electron beam 21 on the observation sample 100.

The objective lens 6 makes, according to a convergence signal supplied from the lens controller 11, the electron beam 21 deflected by the deflector 4 converge as a small spot on the observation sample 100 placed on the sample stage 7.

On the sample stage 7, the semiconductor wafer 100 that is an observation sample is placed.

The detector 8 detects an emitted electron 22 such as a secondary electron or a reflected electron generated from the semiconductor wafer 100 by irradiation with the electron beam 21.

The detection controller 9 amplifies a detection signal from the detector 8, and then converts the detection signal on the basis of a sampling clock from analog to digital signal.

The image processor 10, in cooperation with the computer 13, executes processes such as generating image data on the observation sample 100 on the basis of digital detection data supplied from the detection controller 9, and determining the presence or absence of the defect portion 112 from the obtained image data on the observation sample 100. For this, the image processor 10 includes: an image generator for generating image data based on the digital detection data; an image storage part for storing the image data; an operation part for comparing and computing the image data; and a defect determining part for processing such as defect determination of the defect portion 112 based on the result of comparing and computing processes on the image data.

The lens controller 11 operates and controls the electron gun 3, the deflector 4, the blanking electrode 5, and various electromagnetic lenses such as the objective lens 6 on the basis of observation conditions that reflect inspection conditions supplied from the computer 10.

The deflector controller 12 operates and controls the deflector 4 according to a deflection control instruction based on the observation conditions that reflect the inspection conditions supplied from the lens controller 11.

The computer 13 is connected to the image processor 10, the lens controller 11, the monitor 14, the input instrument 15, and the like, and controls these connected components. In this event, the computer 13 OSD (On Screen Display)-displays an input screen on the monitor 14 for inputting and setting various data as the inspection conditions. Using this input screen, the computer 13 causes the image processor 10 and the lens controller 11 to execute an image capturing process and a defect determining process based on the inspection conditions, in accordance with the inspection conditions based on the inspection parameters inputted and set by operating the input instrument 15. The computer 13 thus acquires the processing results. Then, the processing results thus acquired are displayed and reflected on the input screen that is OSD-displayed on the monitor 14.

The monitor 14 displays the inspection results such as the position of the defect portion 112, the type of the defect portion 112 and the number of defects, and also OSD-displays the input screen for inputting and setting inspection parameters of the inspection conditions.

The input instrument 13 is for operating a GUI (Graphical User Interface) and the like on the input screen OSD-displayed on the monitor 14, and for inputting and setting the inspection parameters. The input instrument 13 has input devices such as, for example, a keyboard and a pointing device.

The SEM-type visual inspection device 1 having such a configuration is configured to inspect the semiconductor wafer 100 as an observation sample in accordance with inspection conditions based on inputted and set inspection parameter, schematically as follows.

The electron beam 21 emitted from the electron gun 3 is deflected by the deflector 4 and converges by the objective lens 6. The semiconductor wafer (observation sample) 100 placed on the sample stage 7 is scanned and irradiated with the electron beam 21. In the irradiation with the electron beam 21 on the semiconductor wafer 100, when a blanking signal is supplied to the blanking electrode 5, the beam trajectory of the electron beam 21 is bent by the blanking electrode 5, so that the semiconductor wafer 100 is not irradiated with the electron beam 21.

Meanwhile, when the emitted electron 22 emitted from the semiconductor wafer 100 by this irradiation with the electron beam 21 reaches the detector 8, the detector 8 detects the emitted electron 22. The detection signal from the detector 8 is amplified by the detection controller 9. Then, the detection signal is converted from analog to digital by the deflector 4 on the basis of a sampling clock in synchronism with scanning with the electron beam 21. Then, this digital detection data is transmitted to the image processor 10, and image data on an observation region on the semiconductor wafer 100 corresponding to the scanning range of the electron beam 21 is generated by the image processor 10. Besides, the image processor 10 determines the presence or absence of the defect portion 112 on the circuit pattern and the type of the defect portion 112, on the basis of the generated image data in which the voltage contrast of the observation region of the semiconductor wafer 100 irradiated with the electron beam 21 reflects a difference in brightness.

Electron Beam Irradiation Method

Next, detailed description will be given of specific irradiation configuration and irradiation method of the electron beam 21 in an inspection of the semiconductor wafer 100 with the above-described SEM-type visual inspection device 1.

In order to emphasize a difference in electrical properties between the normal portion 111 and the defect portion 112 in the semiconductor wafer 100 shown in FIG. 2 and the formulas (1), (2), the SEM-type visual inspection device 1 according to the present embodiment is capable of controlling the irradiation time of the electron beam 21 and the “charge accumulation-waiting time T” between the initial (for example, first) charged-particle beam irradiation for enhancing charge accumulation and the next (for example, second) charged-particle beam irradiation for sample observation by an irradiation method of the electron beam 21.

First, description will be given of how to generate the “charge accumulation-waiting time T” according to the irradiation method of the electron beam 21. The “charge accumulation-waiting time T” is a period between the irradiation with the electron beam 21 for enhancing charge accumulation and the subsequent irradiation for observation, serving as a parameter for observing the normal portion 111 or the defect portion 112 on a circuit pattern of the semiconductor wafer 100 at the optimum surface potential V.

In the inspection, in order to control the time T from the initial (for example, first) electron beam irradiation for enhancing charge accumulation to the subsequent (for example, second) electron beam irradiation for sample observation, that is, the “charge accumulation-waiting time T,” the observation sample 100 needs to be irradiated with the electron beam 21 at least twice or more times.

Herein, how to generate the charge accumulation-waiting time T will be described by taking an example where the observation sample 100 is irradiated with the electron beam 21 twice: the first electron beam irradiation for enhancing charge accumulation and the second electron beam irradiation for observation.

First Method

A first method is a method of generating “charge accumulation-waiting time T” as follows. Specifically, the first electron beam irradiation for enhancing charge accumulation is performed by sequentially irradiating with the electron beam 21 some irradiation positions P1, P2, P3, . . . , Pi sequentially aligned on the observation sample 100 in a scanning line direction of the electron beam 21, the irradiation positions P1, P2, P3, . . . , Pi corresponding to some pixels p1, p2, p3, . . . , pi sequentially aligned on an observation region. Then, the electron beam 21 returns to the original irradiation positions P1, P2, P3, . . . , Pi to start the second electron beam irradiation for sample observation on the irradiation positions P1, P2, P3, . . . , Pi.

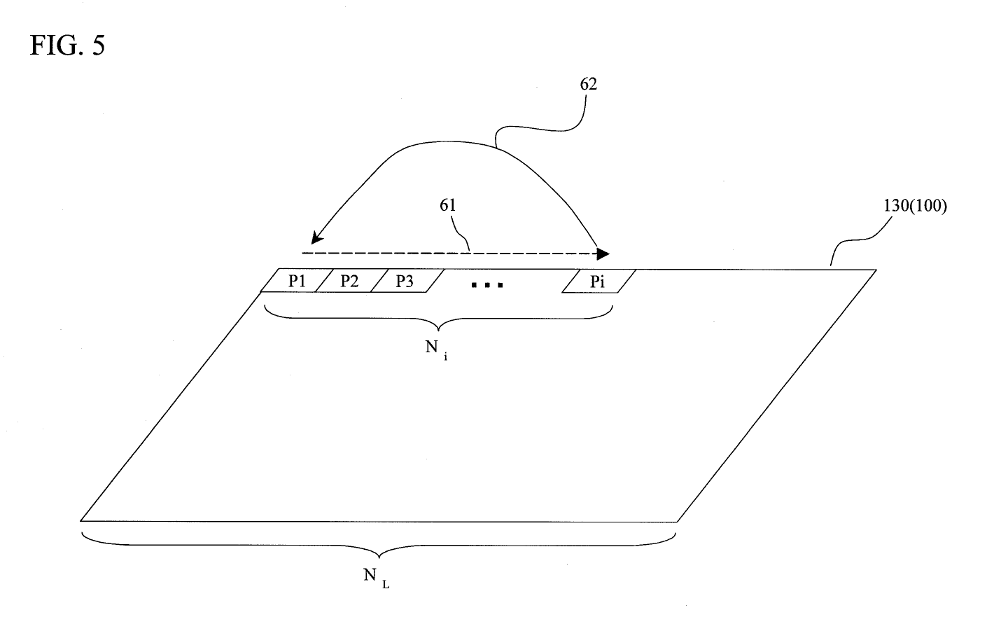

FIG. 5 is an explanatory drawing illustrating a manner that arbitrary number of irradiation positions aligned in a direction of one scanning line with the electron beam are sequentially irradiated with an electron beam, and the electron beam then returns to the original irradiation position.

In FIG. 5, reference numeral 130 denotes an observation region of the observation sample 100. A broken-line arrow 61 illustrates the manner of scanning while irradiating with the electron beam 21 arbitrary number i of the irradiation positions P1, P2, P3, . . . , Pi sequentially aligned on the observation region 130 in the direction of one scanning line with the electron beam 21 (i.e., a direction of a horizontal scanning line). Meanwhile, a solid-line arrow 62 represents a retrace line (horizontal retrace line) of the electron beam 21 to the irradiation position P1 that is a second scanning-starting position from the irradiation position P1 that is the first scanning-terminating position after the first scanning with the electron beam 21 on the arbitrary number i of the irradiation positions P1, P2, P3, . . . , Pi.

In the illustrated example, the charge accumulation-waiting time T for each pixel (each irradiation position) can be represented by a formula (3) where T_{d} is beam irradiation time per pixel (irradiation position) with the electron beam 21, and Nᵢ is the number of pixels (the number of irradiation positions) irradiated with the electron beam 21 after the first irradiation with the electron beam 21 for enhancing charge accumulation is started until the electron beam 21 returns for the second irradiation for observation on the same pixels (the same irradiation positions).

[Mathematical formula 3]

T₍₁₎=Nᵢ×T_{d} (3)

To put it differently, the deflector controller 12 can determine the beam irradiation time T_{d} per pixel (per irradiation position) and the number Nᵢ of pixels (the number of irradiation positions) irradiated with the electron beam 21 until the electron beam 21 returns to the same pixel (the same irradiation position). Thus, if for example the beam irradiation time T_{d} per pixel (per irradiation position) and the number Nᵢ of pixels (the number of irradiation positions) irradiated with the electron beam 21 are set, required charge accumulation-waiting time T can be obtained on a one-to-one basis.

Additionally, in general electron microscopes, the width and the number of pixels to be scanned with the electron beam 21 are predetermined. For this reason, provided that N_{L} is the maximum number of pixels in one scanning line with the electron beam 21, the number Nᵢ of pixels (the number of irradiation positions) irradiated with the electron beam 21 until the electron beam 21 returns to the same pixel (the same irradiation position) and the maximum number N_{L} of pixels in one scanning line with the electron beam 21 have a relationship shown in a formula (4).

[Mathematical formula 4]

Nᵢ<N_{L} (4)

As described above, in one-dimensional scanning within a range of one scanning line with the electron beam 21 in this method, desired required charge accumulation-waiting time T can be generated by the repetitive back and forth movement of the electron beam 21 between the scanning-starting pixel p1 (irradiation-starting position P1) and the scanning-terminating pixel pi (irradiation-terminating position Pi), as long as the beam irradiation time T_{d} per pixel (per irradiation position) and the number Nᵢ of pixels (the number of irradiation positions) irradiated with the electron beam 21 within the range of one scanning line with the electron beam 21 are set as appropriate.

Second Method

A second method is a method of generating “charge accumulation-waiting time T” as follows. Specifically, scanning with the electron beam 21 on each pixel of the maximum number N_{L} of pixels included in the range of one scanning line with the electron beam 21 is performed in the sequence of scanning lines S1, S2, S3, . . . , Si sequentially aligned on an observation region 140 in a direction perpendicular to the scanning direction to perform the first electron beam irradiation for enhancing charge accumulation. Then, the electron beam 21 returns from an irradiation-terminating position P_{S×L} on the last scanning line Si in term of the sequence of the irradiation with the electron beam 21 to the irradiation-starting position P1 on the first scanning line S1 to start the second electron beam irradiation for sample observation.

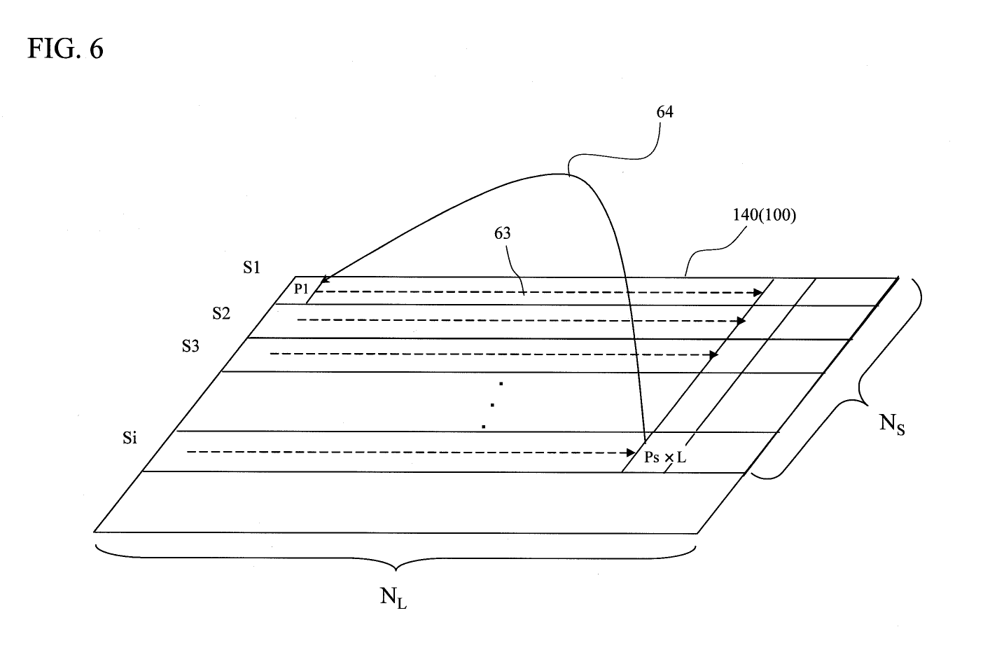

FIG. 6 is an explanatory drawing illustrating a manner that irradiation positions of the maximum number of pixels included in one scanning line with the electron beam are sequentially irradiated with an electron beam for each of the multiple scanning lines, and the electron beam then returns to the irradiation-starting position on the original scanning line.

In FIG. 6, reference numeral 140 denotes an observation region of the observation sample 100. Broken-line arrows 63 thereon illustrate the manner of scanning while sequentially irradiating with the electron beam 21 each of scanning lines S sequentially aligned on the observation region 140 in the sequence of the scanning lines S1, S2, S3, . . . , Si.

Meanwhile, a solid-line arrow 64 represents a retrace line (vertical retrace line) of the electron beam 21 to the scanning-starting pixel p1 (irradiation-starting position P1) on the first scanning line S1 for the second scanning from the scanning-terminating pixel p_{S×L} (irradiation-terminating position P_{S×L}) on the last scanning line Si in the first scanning after the first scanning with the electron beam 21 on the multiple scanning lines S1, S2, S3, . . . , Si.

In the illustrated example, the charge accumulation-waiting time T for each pixel (each irradiation position) can be represented by a formula (5) where Td is beam irradiation time per pixel (per irradiation position) with the electron beam 21, N_{L} is the number of pixels (the number of irradiation positions) in one scanning line S, and N_{S} is the number of the scanning lines S irradiated with the electron beam 21 until the electron beam 21 returns to the same pixel (the same irradiation position).

[Mathematical formula 5]

T₍₂₎=N_{S}×N_{L}×T_{d} (5)

As described above, in two-dimensional scanning on the multiple scanning lines S with the electron beam 21 in this method, desired required charge accumulation-waiting time T can be generated by the repetitive back and forth movement of the electron beam 21 between the scanning-starting pixel p1 (irradiation-starting position P1) on the first scanning line Si in the sequence of the scanning and the scanning-terminating pixel p_{S×L} (irradiation-terminating position P_{S×L}) on the last scanning line Si in the sequence of the scanning, as long as the beam irradiation time T_{d} per pixel (per irradiation position), the number N_{L} of pixels (the number of irradiation positions) irradiated in one scanning line S with the electron beam 21, the number N_{S} of the scanning lines S irradiated with the electron beam 21 until the electron beam 21 returns to the same pixel (the same irradiation position) are set as appropriate.

Third Method

A third method is the above-described first method of performing one-dimensional scanning within the scanning range of one scanning line with the electron beam 21, in which “charge accumulation-waiting time T” is generated as follows. Specifically, in, some irradiation positions P1, P2, P3, . . . , Pi sequentially aligned on the observation sample 100 in the scanning direction of the electron beam 21 are scanned while sequentially irradiated with the electron beam 21 to perform the first electron beam irradiation for enhancing charge accumulation. Then, to start the second electron beam irradiation for sample observation on the irradiation positions P1, P2, P3, . . . , Pi, time T_{b} during which the observation sample 100 is not irradiated with the electron beam 21 is provided when the electron beam 21 returns to the original irradiation position P1 to start the second electron beam irradiation for sample observation.

The time T_{b} during which the observation sample 100 is not irradiated with the primary electron beam 21 can be set by turning OFF the irradiation with the electron beam 21 on the observation sample 100 using the blanking electrode 5.

In the illustrated example, after the first scanning with the electron beam 21 on arbitrary number i of the irradiation positions P1, P2, P3, . . . , Pi sequentially aligned within the scanning range of one scanning line with the electron beam 21, but before the start of the second scanning on the irradiation positions P1, P2, P3, . . . , Pi, the blanking electrode 5 blanks the electron beam 21 only by the time T_{b}. Thus, the formula (3) is modified, and the charge accumulation-waiting time T can be represented as shown in a formula (6).

[Mathematical formula 6]

T₍₃₎=Nᵢ×T_{d}+T_{b} (6)

Note that, in the formula (6), the number Nᵢ of pixels (the number of irradiation positions) irradiated with the electron beam 21 within the scanning range of one scanning line with the electron beam 21 may be ‘0.’ This corresponds to a case where after the first irradiation with the electron beam 21 is performed only on the irradiation position P of one pixel p, the electron beam 21 is blanked for the time T_{b} one time, followed by the second irradiation with the electron beam 21 on the irradiation position P of the same pixel p.

As described above, in one-dimensional scanning within the scanning range of one scanning line with the electron beam 21 in this method, desired required charge accumulation-waiting time T can be generated by further adding, in addition to the charge accumulation-waiting time T₍₁₎ obtained by the repetitive back and forth movement of the electron beam 21 in the first method, the blanking time T_{b} between the first scanning and the second scanning with the electron beam 21, the blanking time T_{b} not depending on the beam irradiation time T_{d} and the number Nᵢ of pixels (the number of irradiation positions) irradiated with the electron beam 21.

Fourth Method

A fourth method is the above-described second method of performing two-dimensional scanning on multiple scanning lines S with the electron beam 21, in which every time one-dimensional scanning with the electron beam 21 on each pixel of the maximum number N_{L} of pixels in one scanning line is completed, time T_{b} during which the observation sample 100 is not irradiated with the electron beam 21 is provided before one-dimensional scanning with the electron beam 21 on the next one scanning line is started.

More specifically, in the first sequential scanning with the electron beam 21 on the multiple scanning lines S1, S2, S3, . . . , Si, the time T_{b} during which the observation sample 100 is not irradiated with the electron beam 21 is provided after the irradiation with the electron beam 21 on one scanning line (for example, scanning line S1) is completed, but before the irradiation with the electron beam 21 on the next one scanning line (for example, scanning line S2) is started.

In this case also, the time T_{b} during which the observation sample 100 is not irradiated with the electron beam 21 can be set by turning OFF the irradiation with the electron beam 21 on the observation sample 100 using the blanking electrode 5.

In the middle of the first scanning on the irradiation positions P1, P2, P3, . . . , P_{S×L} corresponding to the multiple scanning lines S1, S2, S3, . . . , Si, every time the irradiation with the electron beam 21 on one scanning line S is completed, the time T_{b} during which the observation sample 100 is not irradiated is set. Thus, the charge accumulation-waiting time T can be represented as shown in a formula (7).

[Mathematical formula 7]

T₍₄₎=N_{S}×N_{L}×T_{d}+N_{S}×T_{b} (7)

As described above, in two-dimensional scanning with the electron beam 21 on the multiple scanning lines S in this method, desired required charge accumulation-waiting time T can be generated by further adding, in addition to the charge accumulation-waiting time T₍₂₎ obtained by the repetitive back and forth movement of the electron beam 21 in the second method, the blanking time T_{b} every time the irradiation with the electron beam 21 on one scanning line S is completed, the blanking time T_{b} not depending on the beam irradiation time T_{d} and the number Nᵢ of pixels (the number of irradiation positions) irradiated with the electron beam 21.

In the SEM-type visual inspection device 1 according to the present embodiment, the “charge accumulation-waiting time T” is generated between the initial (first) irradiation with the electron beam for enhancing charge accumulation and the next (second) irradiation with the electron beam 21 for sample observation by the aforementioned methods to emphasize the difference in electrical properties between the normal portion 111 and the defect portion 112 in the semiconductor wafer 100.

Note that, in the first to fourth methods of generating the charge accumulation-waiting time T, the charge accumulation-waiting time T₍₁₎ represented by the formula (3) in the first method corresponds to the charge accumulation-waiting time T₍₃₎ represented by the formula (6) in the third method in which the blanking time T_{b} during which the observation sample 100 is not irradiated with the electron beam 21 is ‘0.’ Similarly, the charge accumulation-waiting time T₍₂₎ represented by the formula (5) in the second method corresponds to the charge accumulation-waiting time T₍₇₎ represented by the formula (7) in the fourth method in which the time T_{b} is ‘0.’

For this reason, the way of generating the charge accumulation-waiting time T is selected from the method based on the beam irradiation time T_{d} per pixel (per portion corresponding to one pixel) with the electron beam 21 represented by the formulas (3), (5) and the method based on the blanking time T_{b} during which the observation sample 100 is not irradiated with the electron beam 21 represented by the formulas (6), (7).

Moreover, according to the relationship between the maximum number N_{L} of pixels in one scanning line with the electron beam 21 and the number Nᵢ of pixels (or the number of portions corresponding to the pixels) irradiated with the electron beam 21 represented by the formula (4), and according to the fact that the number N_{S} of the scanning lines S irradiated with the electron beam 21 is an integer of 1 or larger, the relationship between the charge accumulation-waiting time T₍₆₎ represented by the formula (6) in the third method and the charge accumulation-waiting time T₍₇₎ represented by the formula (7) in the fourth method meets a relationship shown in a formula (8).

[Mathematical formula 8]

T₍₇₎>T₍₆₎ (8)

Procedure of Setting Charge Accumulation-Standby Time T

Next, description will be given of setting inspection parameters including the charge accumulation-waiting time T for emphasizing the difference in electrical properties between the normal portion 111 and the defect portion 112 in the semiconductor wafer 100.

In conducting inspection, the SEM-type visual inspection device 1 is capable of setting, as inspection parameters, the parameters in the third method or the fourth method for generating desired required charge accumulation-waiting time T, such as the charge accumulation-waiting time T, the beam irradiation time T_{d} per pixel (per irradiation position), the blanking time T_{b}, the number Nᵢ of pixels (the number of irradiation positions) irradiated with the electron beam 21 within the range of one scanning line, the maximum number N_{L} of pixels in one scanning line, the number N_{S} of the scanning lines S irradiated with the electron beam 21 until the electron beam 21 returns to the same pixel (the same irradiation position).

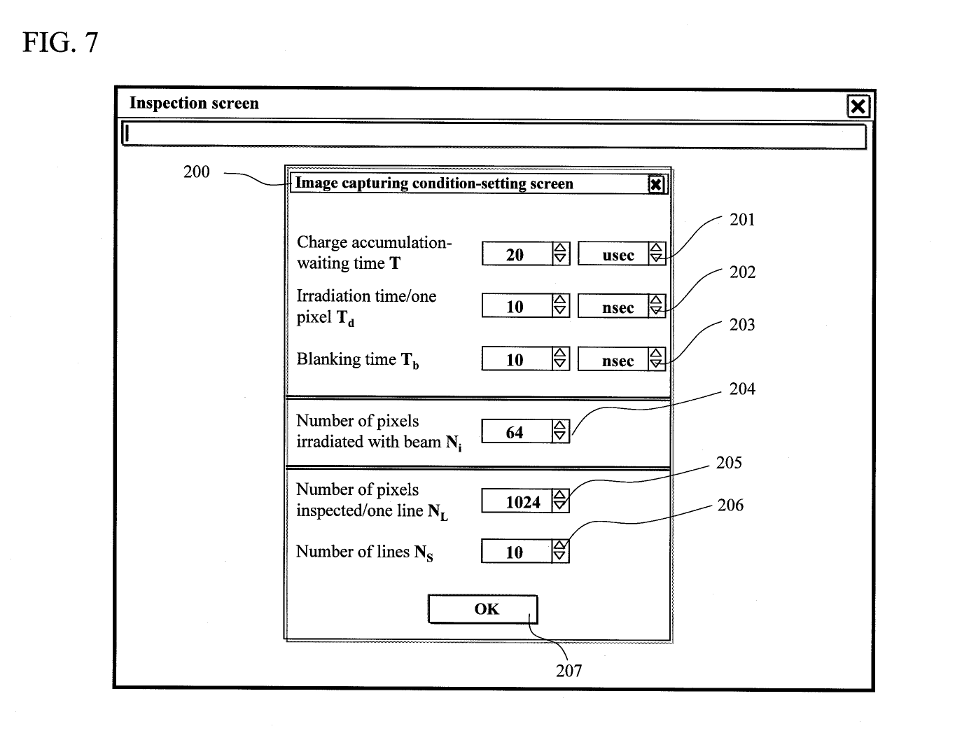

FIG. 7 is a view showing one example of an inspection parameter-input screen as one mode of an input monitor screen in the SEM-type visual inspection device.

An inspection parameter-input screen (displayed as an “image capturing condition-setting screen” in FIG. 7) 200 is displayed in the window on the screen of the monitor 14 by the computer 13 on the basis of given operations through the input instrument 15. In the illustrated example, the inspection parameter-input screen 200 includes: a charge accumulation-waiting time-input column 201 for inputting the charge accumulation-waiting time T (T₍₆₎ or T₍₇₎) common in the third method and the fourth method; an irradiation time-input column 202 for inputting the irradiation time T_{d} with the electron beam 21 per pixel; and a blanking time-input column 203 for inputting the blanking time T_{b}.

Further, the inspection parameter-input screen 200 includes: a beam-irradiated pixel-number-input column 204 for inputting the number Nᵢ of pixels irradiated with the beam within the scanning range of one scanning line with the electron beam 21 for irradiation with the electron beam 21 in using the third method; an inspected pixel-number-input column 205 for inputting the number N_{L} of pixels inspected per one scanning line for irradiation with the electron beam 21 in using the fourth method; and a line-number-input column 206 for inputting the number N_{S} of lines irradiated with the electron beam 21 until the same position is scanned, and has a setting button (OK button) 207 for setting input values of these parameters as the inspection parameters of the inspection conditions.

The operator operates the input instrument 15 to input the value of each parameter according to the inspection parameter-input screen 200 displayed on the monitor 14.

In the case of this example, the operator first inputs and sets a value of any one of the charge accumulation-waiting time T and the irradiation time T_{d} with the electron beam 21 per pixel through the inspection parameter-input screen 200. Here, supposedly, the operator first inputs a value of the charge accumulation-waiting time T.

Next, the operator inputs a value of the other parameter of the charge accumulation-waiting time T and the irradiation time T_{d} with the electron beam 21 per pixel. In this case, a value of the irradiation time T_{d} with the electron beam 21 per pixel is inputted. Incidentally, the value of the irradiation time T_{d} per pixel may be inputted by inputting a sampling frequency f of the electron beam 21 per pixel which defines the irradiation time T_{d} (note that f=1/T_{d}) instead of directly inputting the time as illustrated.

When setting the charge accumulation-waiting time T and the irradiation time T_{d} with the electron beam 21 per pixel as described above, the operator next inputs the blanking time T_{b}.

Then, after completing the parameter inputting of the charge accumulation-waiting time T, the irradiation time T_{d} per pixel, and the blanking time T_{b} which are common in the third method and the fourth method, the operator inputs through the beam-irradiated pixel-number-input column 204 the beam-irradiated pixel-number Nᵢ irradiated with the electron beam 21 within the irradiation range of one scanning line with the electron beam 21 until the electron beam 21 returns to the same position in the case where the charge accumulation-waiting time T₍₆₎ represented by the formula (6) in the third method is selected.

Further, in the case where the charge accumulation-waiting time T₍₇₎ represented by the formula (7) in the fourth method is selected, the operator inputs through the inspected pixel-number-input column 205 and the line-number-input column 206 the number N_{L} of pixels in one scanning line S and the number N_{S} of the scanning lines S irradiated with the electron beam 21 until the electron beam 21 returns to the same pixel (the same irradiation position), respectively.

As described above, to generate the charge accumulation-waiting time T, the third method or the fourth method can be selected, depending on whether the operator inputs the beam-irradiated pixel-number Nᵢ, or whether the operator inputs the number N_{L} of pixels in one scanning line S and the number N_{S} of the scanning lines S. Alternatively, the method can be automatically determined when the charge accumulation-waiting time T is inputted to the charge accumulation-waiting time-input column 201. In this case, as an example, the following configuration may be adopted. Specifically, since the charge accumulation-waiting time T₍₆₎ represented by the formula (6) in the third method and the charge accumulation-waiting time T₍₇₎ represented by the formula (7) in the fourth method have the relationship represented by the formula (8), if the charge accumulation-waiting time T thus set is greater than a predetermined given value, the fourth method represented by the formula (7) is determined; meanwhile, if the charge accumulation-waiting time T thus set is equal to or smaller than the given value, the third method represented by the formula (6) is determined.

Note that, in the above-described case, in inputting these parameters T, T_{d}, T_{b}, Nᵢ, N_{L}, N_{S}, the charge accumulation-waiting time T is inputted at first. Accordingly, depending on the value of the charge accumulation-waiting time T thus inputted, the range of selecting each value of the parameters T_{d}, T_{b}, Nᵢ, N_{L}, Ns is narrowed. This means less selection choices, making the setting easier.

Specifically, if a case in the fourth method represented by the formula (7) is described as an example, when the charge accumulation-waiting time T, the beam irradiation time Td to the same pixel and the blanking time T_{b} are respectively inputted and set to be 100 [usec], 10 [nsec] and 10 [usec], a relationship formula represented by a formula (9) is obtained based on the formula (7).

[Mathematical formula 9]

100000=10×N_{S}×N_{L}+10000×N_{S} (9)

Thereby, the input values of the remaining parameters N_{L}, N_{S} are restricted.

Furthermore, assuming that the input values of the parameters T_{d}, T_{b}, Nᵢ, N_{L}, N_{S} including that of the charge accumulation-waiting time T are a finite number, the selection choices of these input values can be further restricted.

If appropriately inputting the parameters T, T_{d}, T_{b}, N_{L}, Ns through the inspection parameter-input screen 200 as described above, the operator operates the setting button (OK button) 207 to store the parameters T, T_{d}, T_{b}, N_{L}, N_{S} thus inputted through the operation as the inspection parameters of the inspection conditions in the computer 13 of the SEM-type visual inspection device 1.

As a result, a trial inspection region to be described later is determined according to the inspection parameter Nᵢ or the inspection parameters N_{L}, N_{S}, the irradiation conditions of the electron beam 21 on one pixel (one irradiation position) are tentatively determined by the inspection parameters T, T_{d}, T_{b}, Nᵢ or the inspection parameters T, T_{d}, T_{b}, N_{L}, Ns.

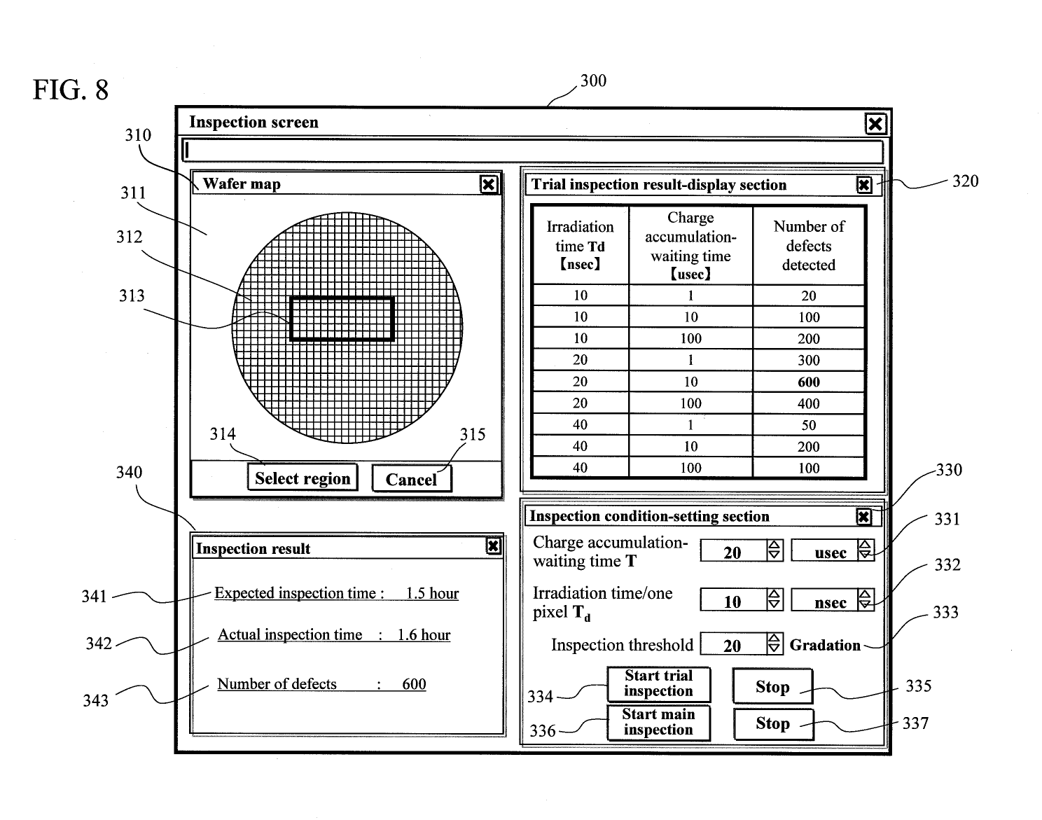

Once the inspection parameters T, T_{d}, T_{b}, Nᵢ, N_{L}, N_{S} are determined through the operation on the setting button 207, the computer 13 of the SEM-type visual inspection device 1 then displays an inspection starting screen (displayed as an “inspection screen” in FIG. 8) 300 as shown in FIG. 8 based on the inspection parameters T, T_{d}, T_{b}, Nᵢ, N_{L}, N_{S} in place of the inspection parameter-input screen 200 in the window on the screen of the monitor 14.

FIG. 8 is a view showing one example of the inspection starting screen as one mode of the input monitor screen in the SEM-type visual inspection device.

In the illustrated example, the inspection starting screen 300 is configured to have an inspection region-selection window 310, a trial inspection result-display window 320, an inspection condition-setting window 330, and an expected/inspection result-display window 340.

The inspection region-selection window (displayed as a “wafer map” in FIG. 8) 310 includes a wafer map-display section 311. The wafer map-display section 311 displays a wafer map 312 for determining an inspection region of the semiconductor wafer 100 that is an observation sample based on an inspection recipe selected in advance. The operator can set an inspection region 313 on this wafer map 312 by operating an input device of the input instrument 15.

Moreover, the inspection region-selection window 310 is further provided with: a region selection key 314 for registering the inspection region 313 as an actual inspection region of the semiconductor wafer 100 that is an observation sample, the inspection region 313 having been set on the wafer map 312 of the inspection region-selection window 310; and a cancel key 315 for cancelling the registration setting of the inspection region 313 as the actual inspection region by the operation on the region selection key 314.

Thereby, the operator can set and reset any inspection region of the semiconductor wafer 100 that is an observation sample on the wafer map 312 displayed in the inspection region-selection window 310.

The trial inspection result-display window (displayed as a “trial inspection result-display section” in FIG. 8) 320 displays a list of inspection results of “trial inspections” in a comparable manner, the “trial inspections” each having been conducted by operating a trial inspection-start button 334 to be described later before an “actual inspection” (hereinafter referred to as a “main inspection”) is conducted on the inspection region 313 set on the semiconductor wafer 100 that is an observation sample through the inspection region-selection window 310.

Herein, the “trial inspection” refers to a pilot inspection conducted on a trial inspection region of the semiconductor wafer 100 that is an observation sample on the basis of the set inspection conditions, the trial inspection region having a further restricted size relative to the inspection region 313 which is to be actually subjected to electron beam inspection subsequently. In the case of this example, this trial inspection region is determined together with the charge accumulation-waiting time T when the inspection parameter Nᵢ or the inspection parameters N_{L}, N_{S} are inputted and set using the inspection parameter-input screen 200.

In the illustrated example, the trial inspection result-display window 320 displays a list of a combination of inspection parameters of the irradiation time T_{d} per pixel and the charge accumulation-waiting time T for each trial inspection, as well as the number of defects detected on the trial inspection regions in the trial inspections using these inspection parameters, the combination and the number of defects detected being in association with each other. The number of defects detected in each trial inspection is displayed in a manner comparable with that in another trial inspection.

The inspection condition-setting window (illustrated as an “inspection condition-setting section” in FIG. 8) 330 includes a charge accumulation-waiting time-setting column 331 for setting the charge accumulation-waiting time T in the “the main inspection” or the “trial inspection,” an irradiation time-setting column 332 for setting the beam irradiation time T_{d} per pixel, an inspection threshold-setting column 333 for setting an inspection threshold, a trial inspection-start button 334 for starting the trial inspection, a trial inspection-stop button 335 for stopping the trial inspection currently conducted, a main inspection-start button 336 for starting the main inspection, and a main inspection-stop button 337 for stopping the main inspection currently conducted.

On an initial display of the inspection starting screen 300, the charge accumulation-waiting time-setting column 331 and the irradiation time-setting column 332 of the inspection condition-setting window 330 are set to display values of the charge accumulation-waiting time T and the irradiation time T_{d} per pixel, the values having been respectively inputted to the charge accumulation-waiting time-input column 201 and the irradiation time-input column 202 of the above-described inspection parameter-input screen 200. Through the inspection condition-setting window 330, the operator can change the settings of the values set and displayed in the charge accumulation-waiting time-setting column 331 and the irradiation time-setting column 332 as described above by operating an input device of the input instrument 15.

Moreover, in a case where the operator resets at least any value of the charge accumulation-waiting time T and the irradiation time T_{d} per pixel through the inspection condition-setting window 330 of the inspection starting screen 300, the computer 13 of the SEM-type visual inspection device 1 is configured to change the value of the charge accumulation-waiting time T or the irradiation time T_{d} per pixel having been set beforehand through the inspection parameter-input screen 200 to a value reset through the inspection condition-setting window 330 of the inspection starting screen 300. In accordance with this change in the value, the computer 13 thus resets the values of other inspection parameters that need to be adjusted, for example, the value of the blanking time T_{b}, and automatically sets the inspection conditions based on the inspection parameters corresponding to this setting change.

Further, to the inspection threshold-setting column 333, the operator inputs and sets a gradation level of the luminance of an observation image captured from the semiconductor wafer 100 that is an observation sample, the gradation level serving as the inspection threshold for discriminating the normal portion 111 and the defect portion 112 from the observation image.

In a case where the operator operates the trial inspection-start button 334 with the charge accumulation-waiting time T, irradiation time T_{d} per pixel, and the inspection threshold having been set through such an inspection condition-setting window 330, the computer 13 of the SEM-type visual inspection device 1 is configured to control each component connected thereto, and conduct while controlling the trial inspection on the trial inspection region having a restricted size relative to the inspection region 313 under the inspection conditions thus set. Meanwhile, in a case where the operator operates the main inspection-start button 336, the computer 13 of the SEM-type visual inspection device 1 is configured to control each component connected thereto, and conduct while controlling the main inspection on the inspection region 313 under the inspection conditions thus set.

The expected/result-display window (displayed as an “inspection result” in FIG. 8) 340 is configured to have an expected inspection time-display column 341, an actual inspection time-display column 342, and a defect-number-display column 343. The expected inspection time-display column 341 displays expected inspection time of the trial inspection or the main inspection in a case where the trial inspection or the main inspection is conducted on the basis of the charge accumulation-waiting time T displayed in the charge accumulation-waiting time-setting column 331 of the inspection condition-setting window 330 and the irradiation time T_{d} per pixel displayed in the irradiation time-setting column 332, the expected inspection time being computed by the computer 13. The actual inspection time-display column 342 displays actual inspection time of the trial inspection or the main inspection which have been actually conducted. The defect-number-display column 343 displays the number of the defect portions 112 detected by the image processor 10 in the trial inspection or the main inspection.

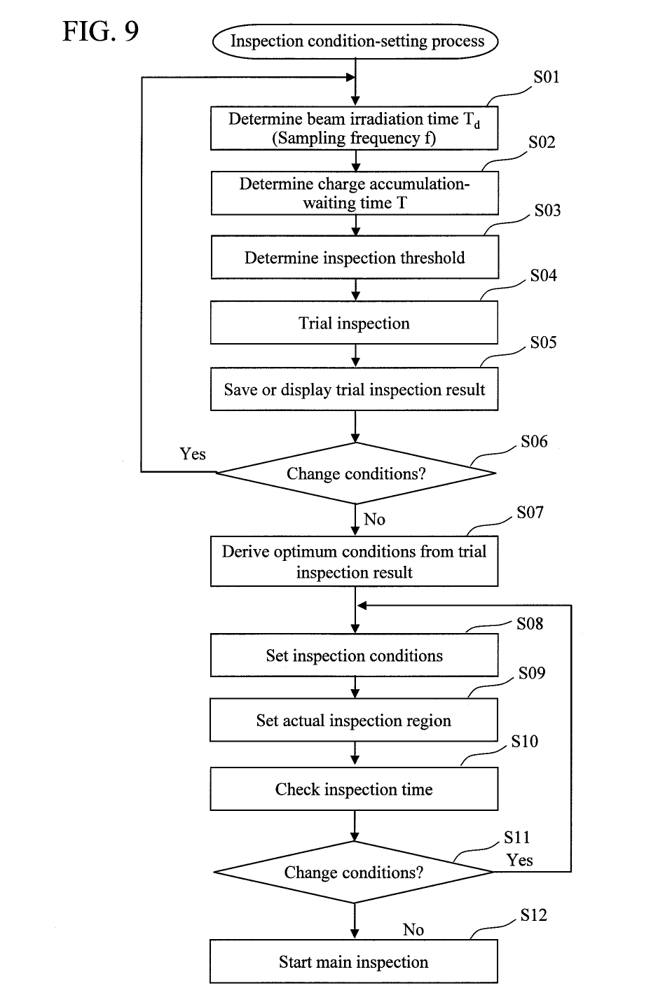

Next, with reference to FIG. 9, description will be given of an inspection condition-setting process including the trial inspection the SEM-type visual inspection device 1 conducts according to the above-described inspection starting screen 300 until the operator performs the main inspection on the inspection region 313.

FIG. 9 is a flowchart of the inspection condition-setting process executed when the SEM-type visual inspection device conducts an actual inspection.

For example, if the operator completes inputting of the inspection parameters T, T_{d}, T_{b}, Nᵢ, N_{L}, Ns appropriately through the inspection parameter-input screen 200, the computer 13 of the SEM-type visual inspection device 1 OSD-displays the inspection starting screen 300 on the monitor 14 and executes the inspection condition-setting process shown in FIG. 9. In this event, while referring to the expected inspection time displayed in the expected inspection time-display column 341 of the expected/result-display window 300, the operator can adjust the charge accumulation-waiting time T and the irradiation time T per pixel through the inspection condition-setting window 330.

Using the inspection condition-setting window 330 of the inspection starting screen 300 through the operation on the input instrument 15, the operator determines irradiation time T_{d} per pixel (Step S01), determines the charge accumulation-waiting time T (Step S02), determines the inspection threshold (Step S03), and operates the trial inspection-start button 334. When this is detected, the computer 13 of the SEM-type visual inspection device 1 controls each component under the inspection conditions thus set, and conducts the trial inspection on a trial inspection region having a restricted size relative to the actual inspection region 313 (Step S04).

This trial inspection is conducted on the trial inspection region of the semiconductor wafer 100 that is an observation sample. The trial inspection region is defined by the number Nᵢ of pixels irradiated with the beam, or the number N_{L} of pixels in one scanning line S and the number N_{S} of the scanning lines S irradiated with the electron beam 21 in the irradiation method of the electron beam 21 selected from any one of the third method with the charge accumulation-waiting time T₍₆₎ in the formula (6) and the fourth method with the charge accumulation-waiting time T₍₇₎ in the formula (7) after the operator adjusts the values of the inspection parameters T_{d}, T, T_{b} having been inputted beforehand through the inspection parameter-input screen 200 in accordance with the irradiation time T_{d} per pixel and the charge accumulation-waiting time T determined through the inspection condition-setting window 330 of the inspection starting screen 300.

By conducting this trial inspection, the computer 13 of the SEM-type visual inspection device 1 saves the inspection result in association with the inspection parameters as the inspection conditions in the unillustrated storage part, the inspection result including the number of defects detected by the image processor 10 based on the inspection threshold. Moreover, the computer 13 displays the result in the trial inspection result-display window 320 of the inspection starting screen 300 and in the actual inspection time-display column 342 and the defect-number-display column 343 of the expected/result-display window 340 (Step S05).

If it is necessary to change the inspection conditions by resetting the values of the inspection parameters such as the charge accumulation-waiting time T based on the comparison among the inspection results of the trial inspections displayed in the trial inspection result-display window 320 of the inspection starting screen 300, the comparison between the expected inspection time and the actual inspection time of this current trial inspection displayed in the expected/result-display window 340, and the like (Step S06), the operator returns to Step 1, changes the inspection conditions, and again conducts the trial inspection (Steps S01 to S05).

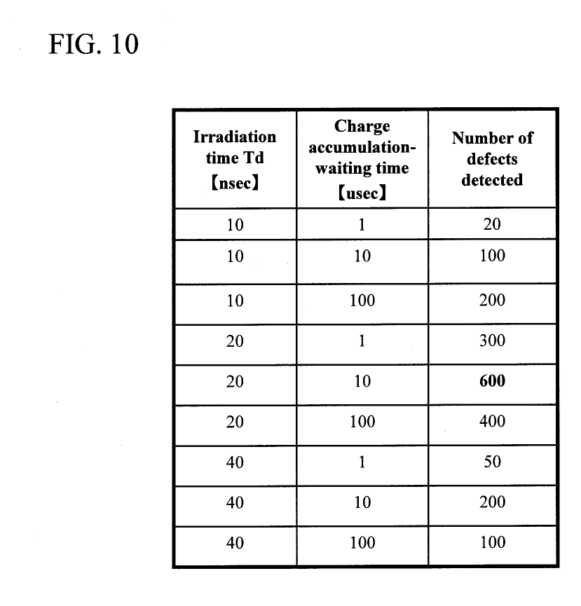

As described above, when the operator performs the trial inspection process from Steps 1 to 5 an appropriate number of times under different inspection conditions, every time the inspection result of the trial inspection is acquired, the computer 13 accumulatively stores the number of defects detected in the trial inspection and the inspection parameters such as the irradiation time T_{d} per pixel (sampling frequency f, f=1/T_{d}) and the charge accumulation-waiting time T in association with each other for each trial inspection in the unillustrated storage part of the computer 13 as shown in FIG. 10, for example.

FIG. 10 is a table for explaining the stored data accumulatively stored in the storage part as a result of the trial inspections repeated several times while the inspection conditions are changed.

Then, in Step 5, the computer 13 displays the results of the trial inspections repeated several times while the inspection conditions are changed in the trial inspection result-display window 320 of the inspection starting screen 300 as shown in FIG. 8, the results including the current trial inspection result. The operator thus can compare the irradiation time T_{d} per pixel, the charge accumulation-waiting time T, and the number of defects detected for each trial inspection, and derive optimum inspection conditions. In addition, the computer 13 displays the current trial inspection result and the actual inspection time in the actual inspection time-display column 342 and the defect-number-display column 343 of the expected/result-display window 340 so that the operator can make comparison with what have been expected.

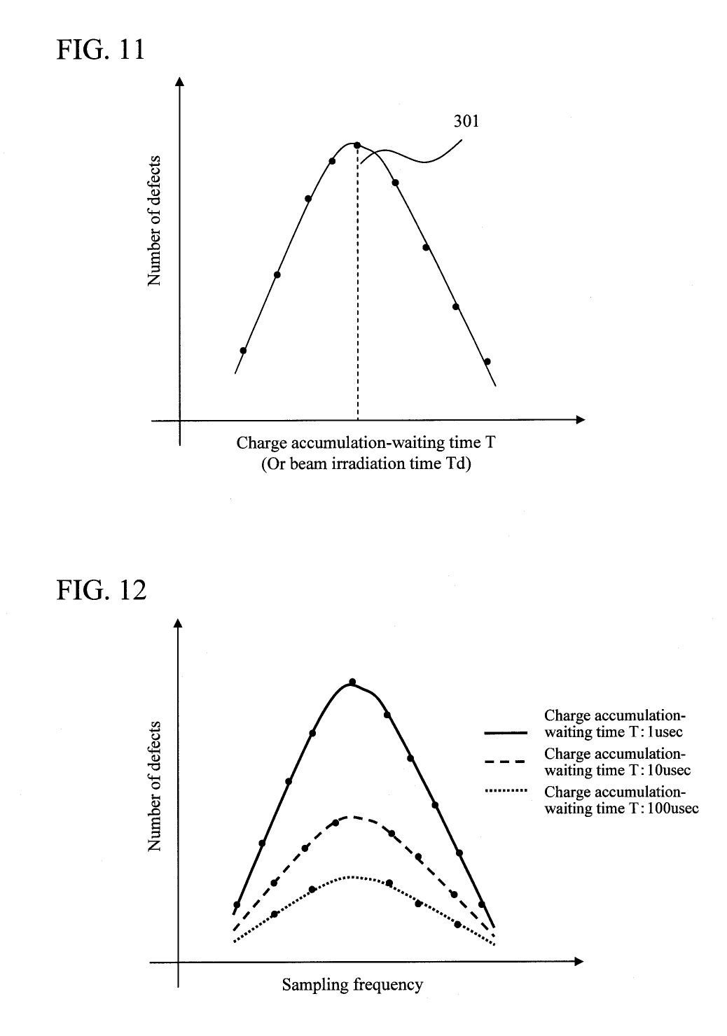

Note that the inspection result-display window 320 shown in FIG. 8 is configured to display a list of the results of the trial inspections repeated several times while the inspection conditions are changed including the current trial inspection result in association with the irradiation time T_{d} per pixel, the charge accumulation-waiting time T, and the number of defects detected for each trial inspection. Alternatively, it is possible to display graphs as shown in FIGS. 11 and 12 so that the operator can derive optimum inspection conditions.

FIG. 11 is an example of the result of the trial inspections repeated several times while the inspection conditions are changed, the result displayed in the form of a graph in the inspection result-display window based on a relationship between the charge accumulation-waiting time T or the beam irradiation time T_{d} and the number of defects.

FIG. 12 is an example of the result of the trial inspections repeated several times while the inspection conditions are changed, the result displayed in the form of a graph in the inspection result-display window based on a relationship between the sampling frequency f and the number of defects.

The graph displayed based on the relationship between the charge accumulation-waiting time T or the beam irradiation time T_{d} and the number of defects shown in FIG. 11 can facilitate visual comparison of the number of defects corresponding to each charge accumulation-waiting time T or each beam irradiation time T_{d}. Thus, the operator easily derives the charge accumulation-waiting time T and the beam irradiation time T_{d} as the optimum inspection conditions.

The graph displayed based on the relationship between the sampling frequency f and the number of defects shown in FIG. 12 can facilitate visual comparison of the number of defects corresponding to the sampling frequency f (f=1/T_{d}, beam irradiation time T_{d}) under each charge accumulation-waiting time T. Thus, the operator easily derives the charge accumulation-waiting time T and the beam irradiation time T_{d} as the optimum inspection conditions.

If it is not necessary to conduct the trial inspection by resetting the values of the inspection parameters such as the charge accumulation-waiting time T (Step S06), the operator derives the optimum inspection conditions as described above, while referring to the result of the trial inspections repeated several times while the inspection conditions are changed, the result displayed in the inspection result-display window 320 (Step S07). In the example shown in FIGS. 8 and 10, the operator can easily derive as the optimum inspection conditions the combination of the beam irradiation time T_{d} of 10 [usec] and the charge accumulation-waiting time T of 10 [nsec] where the beam irradiation time T_{d} and the charge accumulation-waiting time T, particularly the charge accumulation-waiting time T, are not relatively longer than those in the other trial inspection results, and a larger number (600) of the defect portions 112 were successfully detected than those under the other inspection conditions (Step S07).

The operator operates the input instrument 15 to set the derived beam irradiation time T_{d} and charge accumulation-waiting time T as the inspection conditions to the irradiation time-setting column 332 and the charge accumulation-waiting time-setting column 331 in the inspection condition-setting window 330 of the inspection starting screen 300 (Step S08). As a specific way of the setting, instead of direct setting to the irradiation time-setting column 332 and the charge accumulation-waiting time-setting column 331 in the inspection condition-setting window 330, by designating the trial inspection result obtained under the optimum inspection conditions through the inspection result-display window 320, the computer 13 can automatically set the corresponding beam irradiation time T_{d} and charge accumulation-waiting time T to the irradiation time-setting column 332 and the charge accumulation-waiting time-setting column 331 in the inspection condition-setting window 330.

Incidentally, the above-described process from Steps 1 to 8 may be automatically sequenced as follows, in a case, for example, where inspection parameters to be changed are determined in advance by a recipe or the like. Specifically, the computer 13 conducts while controlling some trial inspections with the values of the inspection parameters being changed on the basis of the default values. The computer 13 determines and sets the optimum inspection conditions as the inspection conditions on the basis of the result of each trial inspection.

Then, when the optimum inspection conditions obtained as described above are set, the operator operates an input device of the input instrument 15 to designate the inspection region 313 on the wafer map 312 displayed in the wafer map-display section 311 of the inspection region-selection window 310. Through an operation on the region selection key 314, the designated inspection region 313 is set as an inspection region 313 in the main inspection (Step S09).

When the inspection region 313 in the main inspection is set on the wafer map 312 displayed in the wafer map-display section 311, the computer 13 computes expected inspection time for this inspection region 313 in the main inspection, and displays the expected inspection time in place of that in the trial inspection in the expected inspection time-display column 341 of the expected/result-display window 340. In this event, the displays of the actual inspection time-display column 342 and the defect-number-display column 343 of the wafer map-display section 311 are reset for preparation to start the main inspection (Step S10).

In other words, when the inspection region 313 in the main inspection is set in Step S09, the expected inspection time for the inspection region 313 thus set in the main inspection, that is, an inspection throughput Tₜₕ of the main inspection is computed in Step S10.

The computer 13 computes the inspection throughput Tₜₕ of the main inspection, for example, as described below.

The inspection throughput of the main inspection, that is, the time Tₜₕ for the inspection region 313 in the main inspection, is obtained by a relationship formula represented by a formula (10) where S [nm²] is an area of the inspection region 313 thus set in the main inspection, T_{L} [sec] is net time for irradiation with one scanning line (one line) of the electron beam 21, p [nm] is a size of an inspected pixel, and L nm is a length of one scanning linewidth (one linewidth).

$$\begin{matrix}[ Mathematical formula 10 ] & \\ {T}_{th} ∝ \frac{S}{p \times L} \times {T}_{L} [ sec ] & ( 10 )\end{matrix}$$

Here, the net time T_{L} [sec] for irradiation with one scanning line (one line) of the electron beam 21 relates to the charge accumulation-waiting time T. For example, if the number of times of waiting for the charge accumulation-waiting time T is set N, the same position is irradiated with the electron beam 21 (N+1) times. Accordingly, the net time T_{L} [sec] for irradiation with one line of the electron beam 21 can be represented by a formula (11).

[Mathematical formula 11]

T_{L}=(N+1)×T [sec] (11)

Meanwhile, in the formula (11), the charge accumulation-waiting time T is determined by a value set under the conditions of the equations of the formulas (3) to (8).

As a result, the formulas (10) and (11) indicate that the charge accumulation-waiting time T and the inspection time Tₜₕ have a proportional relationship. This means that as the charge accumulation-waiting time T simply increases, the inspection time Tₜₕ for the inspection region 313 in the main inspection slows down.

For this reason, after checking the expected inspection time for the main inspection displayed in the expected inspection time-display column 341 of the expected/result-display window 34 in Step 10, if the operator would like to further improve the throughput, the operator changes the optimum inspection conditions determined in Step 8 (Step S11).

In other words, the operator repeats the process from Steps 8 to 11 until it is checked that all of the charge accumulation-waiting time T and the beam irradiation time T_{d} set as the optimum inspection conditions based on the trial inspection, the number of defects detected in the trial inspection, and the expected inspection time for the main inspection under these optimum inspection conditions are optimum conditions. Then, the operator adjusts the charge accumulation-waiting time T and the beam irradiation time T_{d} set as the optimum inspection conditions, and the size (area) of the inspection region 313 for the main inspection.

As a result, after checking that the display contents of the windows 310, 320, 330, 340 on the inspection starting screen are the optimum inspection conditions for the main inspection altogether, the operator operates the main inspection-start button 336 of the inspection condition-setting window 330 to start the main inspection on the inspection region 313 (Step S12).

Incidentally, the above-described process from Steps 8 to 11 may be automatically sequenced as follows, in a case, for example, where the maximum acceptable inspection time and the size of the inspection region are determined in advance by a recipe or the like. Specifically, the computer 13 determines and sets the optimum inspection conditions as the inspection conditions while changing the values of the inspection parameters on the basis of the default values.

To put it differently, in a case, for example, where the inspection parameters to be changed are determined, or where the maximum acceptable inspection time and the size of the inspection region are determined, in advance by a recipe or the like, the computer 13 can execute automatically all of the inspection condition-setting process shown in FIG. 9 in cooperation with each component of the device.

Note that the inspection condition-setting process in the SEM-type visual inspection device 1 according to the present embodiment has been described based on the inspection parameter-input screen 200 shown in FIG. 7 and the inspection starting screen 300 shown in FIG. 8. Nevertheless, the inspection condition-setting process shown in FIG. 9 is not restricted to the method based on the inspection parameter-input screen 200 and the inspection starting screen 300 described above. Various changes are possible, as long as the optimum inspection conditions for the main inspection are set based on the result of the trial inspection.

### Second Embodiment

### Configuration

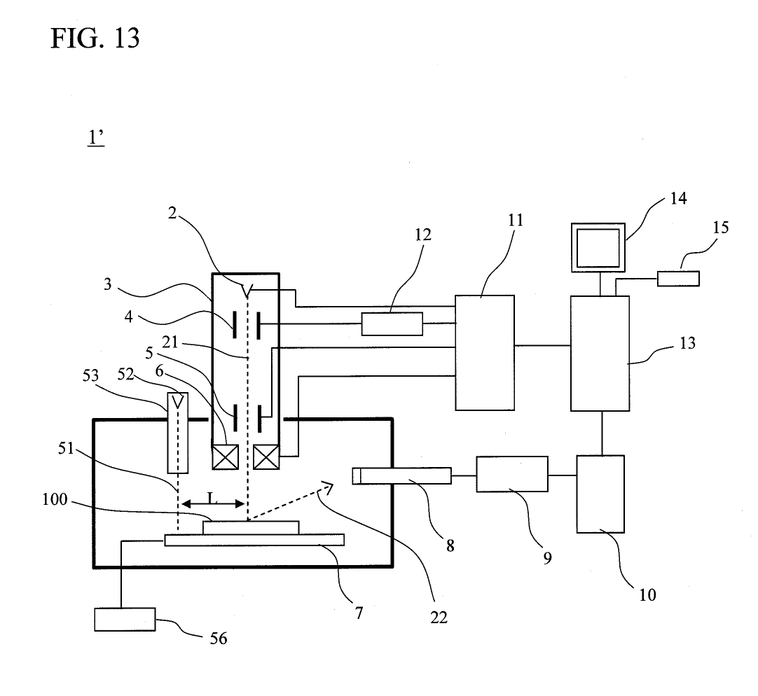

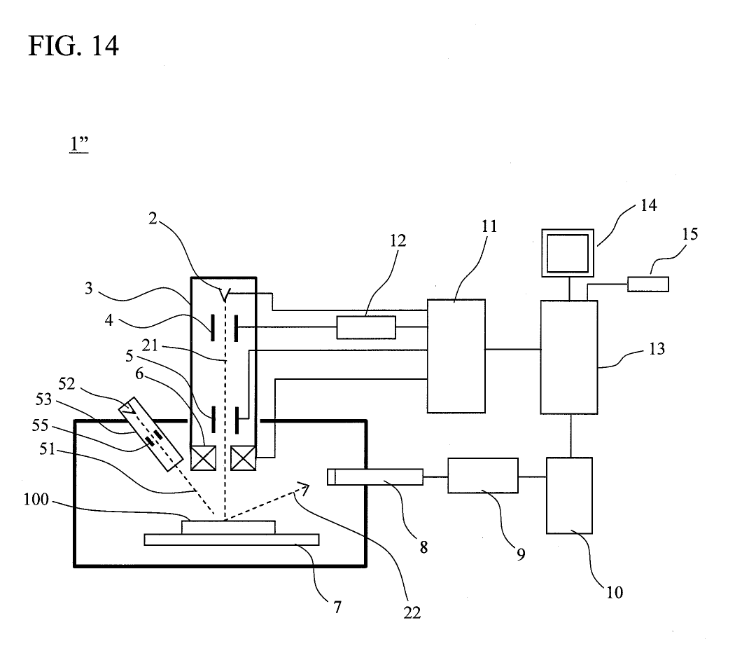

FIGS. 13 and 14 are configuration diagrams of examples of an SEM-type visual inspection device according to the present embodiment, the SEM-type visual inspection device including at least two or more electron gun for electron beam irradiation.

Note that, in the description of the configuration, constituent components which are the same as or similar to those of the SEM-type visual inspection device 1 shown in FIG. 4 are denoted by the same reference numerals, and description thereof will be omitted.

In FIGS. 13 and 14, both SEM-type visual inspection devices 1′, 1″ in any examples include at least one or more first electron guns 53 for irradiating the observation sample 100 with an electron beam 51 from an electron source 52 to control the charged state of the observation sample 100, and also include a second electron gun 3 for irradiating the observation sample 100 with the electron beam 21 from the electron source 2 to form a microscope image with the emitted electron 22 from the observation sample 100.

Besides, in the SEM-type visual inspection device 1′ shown in FIG. 13, the irradiation site of the electron beam 51 from the first electron gun 53 is different from the irradiation site of the electron beam 21 from the second electron gun 3. For this reason, the observation sample 100 placed on the sample stage 7 is configured to be movable between the irradiation site of the electron beam 51 from the first electron gun 53 and the irradiation site of the electron beam 21 from the second electron gun 3 by driving the sample stage 7. Thereby, the observation sample 100 can be irradiated with either the electron beam 51 from the first electron gun 53 or the electron beam 21 from the second electron gun 3, depending on a position where the sample stage 7 is driven.

In contrast, the SEM-type visual inspection device 1″ shown in FIG. 14 is configured such that the irradiation site of the electron beam 51 from the first electron gun 53 matches the irradiation site of the electron beam 21 from the second electron gun 3. For this reason, similarly to the second electron gun 3, the first electron gun 53 also includes a blanking electrode 55 so as not to irradiate the observation sample 100 with the electron beam 51. Thereby, even though the irradiation site of the electron beam 51 from the first electron gun 53 matches the irradiation site of the electron beam 21 from the second electron gun 3, the observation sample 100 can be irradiated alternatively with either the electron beam 51 or the electron beam 21 at a different timing.

Incidentally, the SEM-type visual inspection device 1″ shown in FIG. 14 is configured such that the first electron gun 53 includes the blanking electrode 55 so as not to irradiate the observation sample 100 with the electron beam 51. Alternatively, instead of providing with blanking electrode 55, an electron gun having a function of stopping electron beam emission from the electron source 52 to prevent the electron beam 51 from reaching the observation sample 100 can be used as the first electron gun 53.

Moreover, in both the SEM-type visual inspection devices 1′, 1″ in any examples, the way of irradiation with the electron beam 51 from the first electron gun 53 may be scanning on the observation sample 100 or surface irradiation on the observation sample 100 with a relatively large beam diameter.

Electron Beam Irradiation Method

Next, detailed description will be given of specific irradiation configuration and irradiation method of the electron beams 51, 21 with the first, second electron guns 53, 3 in an inspection of the semiconductor wafer 100 with the above-described SEM-type visual inspection devices 1′, 1″.

In order to emphasize a difference in electrical properties between the normal portion 111 and the defect portion 112 in the semiconductor wafer 100 shown in FIG. 2 and the formulas (1) and (2), the SEM-type visual inspection devices 1′, 1″ according to the present embodiment are capable of controlling the “charge accumulation-waiting time T” between the initial (for example, first) charged-particle beam irradiation and the next (for example, second) charged-particle beam irradiation by using the first, second electron guns 53, 3.

For this, the SEM-type visual inspection devices 1′, 1″ are configured to control time between the irradiation with the electron beam 51 from the first electron gun 53 on the observation sample 100 and the irradiation with electron beam 21 from the second electron gun 3, thereby controlling the “charge accumulation-waiting time T.” Description will be given of the irradiation method of the electron beams 51, 21 using the first, second electron guns 53, 3 to generate this “charge accumulation-waiting time T.”

First Method

In the SEM-type visual inspection device 1′ shown in FIG. 13 in which the irradiation site of the electron beam 51 from the first electron gun 53 is different from the irradiation site of the electron beam 21 from the second electron gun 3, a stage-driving control system 56 provided to the sample stage 7 is configured to drive and control the sample stage 7 in a way that the observation sample 100 is movable between the irradiation site of the electron beam 51 and the irradiation site of the electron beam 21. In this case, the driving configuration of the sample stage 7 may be that the sample stage 7 is moved by being continuously driven, or by step & repeat in which driving and stopping are repeated. In this event, the computer 13 controls the stage moving speed of the sample stage 7 by the stage-driving control system 56 in accordance with the “charge accumulation-waiting time T” as follows.

In a case where the sample stage 7 is continuously driven at, for example, a constant stage moving speed v, the charge accumulation-waiting time T from the initial (for example, first) electron beam irradiation for enhancing charge accumulation with the first electron gun 53 on the observation sample 100 until the subsequent (for example, second) electron beam irradiation for observation with the second electron gun 3 can be represented by a formula (12) where L is a distance between an optical axis of the electron beam 51 at the irradiation site of the first electron gun 53 and an optical axis of the electron beam 21 at the irradiation site of the second electron gun 3.

$$\begin{matrix}[ Mathematical formula 12 ] & \\ T = \frac{L}{v} & ( 12 )\end{matrix}$$

Meanwhile, provided that v is a stage moving speed of the sample stage 7 driven by step & repeat and Tₛ is total stopping time when the sample stage 7 is stopped, the charge accumulation-waiting time T can be represented by a formula (13).

$$\begin{matrix}[ Mathematical formula 13 ] & \\ T = {T}_{s} + \frac{L}{v} & ( 13 )\end{matrix}$$

In other words, in the case where the first, second electron guns 53, 3 are provided and where the initial irradiation site of the electron beam 51 for enhancing charge accumulation with the first electron gun 53 is different from the subsequent irradiation site of the electron beam 21 for observation with the second electron gun 3, the distance L between the optical axis of the electron beam 51 at the irradiation site of the first electron gun 53 and the optical axis of the electron beam 21 at the irradiation site of the second electron gun 3 is constant. If the stage moving speed v of the sample stage 7 and the total stopping time Tₛ in the step & repeat can be determined, required charge accumulation-waiting time T can be obtained on a one-to-one basis.

Second Method

The SEM-type visual inspection device 1″ shown in FIG. 14 in which the irradiation site of the electron beam 51 from the first electron gun 53 matches the irradiation site of the electron beam 21 from the second electron gun 3 is configured to perform an initial (for example, first) irradiation with the electron beam 51 for enhancing charge accumulation from the first electron gun 53, then stop this irradiation with the electron beam 51, and perform the next (for example, second) irradiation with the electron beam 21 for observation from the second electron gun 3. Accordingly, the SEM-type visual inspection device 1″ is configured to stop the irradiation with the electron beam 51 from the first electron gun 53 at the time of the irradiation with the electron beam 21 from the second electron gun 3. Hence, the detector 8 never detects an emitted electron generated by the irradiation with the electron beam 51 for enhancing charge accumulation from the first electron gun 53, but only detects an emitted electron generated by the irradiation with the electron beam 21 for observation from the second electron gun 3. Thereby, an electron microscope image is captured. In this event, the irradiation with the electron beam 51 from the first electron gun 53 and the irradiation with the electron beam 21 from the second electron gun 3 are stopped, for example, by operating and controlling the blanking electrodes 55, 5 respectively by the lens controller 11.

Thus, the charge accumulation-waiting time T from the initial (for example, first) electron beam irradiation for enhancing charge accumulation with the first electron gun 53 on the observation sample 100 until the subsequent (for example, second) electron beam irradiation for observation with the second electron gun 3 can be represented by a formula (14) where T_{bb} is time from the irradiation with the electron beam 51 for enhancing charge accumulation from the first electron gun 53 on the observation sample 100 followed by stopping of the irradiation with the electron beam 51 from the first electron gun 53 until the irradiation with the electron beam 21 for observation from the second electron gun 3 on the observation sample 100.

[Mathematical formula 14]

T=Tₕₕ (14)

In other words, in the case where the first, second electron guns 53, 3 are provided and where the initial irradiation site of the electron beam 51 for enhancing charge accumulation with the first electron gun 53 matches the subsequent (for example, second) irradiation site of the electron beam 21 for observation with the second electron gun 3, if the time T_{bb} from the irradiation with the electron beam 51 for enhancing charge accumulation from the first electron gun 53 on the observation sample 100 followed by stopping the irradiation with the electron beam 51 from the first electron gun 53 until the irradiation with the electron beam 21 for observation from the second electron gun 3 on the observation sample 100 can be determined, required charge accumulation-waiting time T can be obtained on a one-to-one basis.

Procedure of Setting Charge Accumulation-Standby Time T

In the present embodiment, the inspection parameters including the charge accumulation-waiting time T for emphasizing the difference in electrical properties between the normal portion 111 and the defect portion 112 in the semiconductor wafer 100 are set depending on the difference in device configuration between the SEM-type visual inspection devices 1′, 1″: whether the irradiation site of the electron beam 51 from the first electron gun 53 is different from or matches the irradiation site of the electron beam 21 from the second electron gun 3 as follows.

In the SEM-type visual inspection device 1′ shown in FIG. 13 in which the irradiation site of the electron beam 51 is different from the irradiation site of the electron beam 21, the distance L between the optical axis of the electron beam 51 and the optical axis of the electron beam 21 at the respective irradiation sites is fixed. Thus, in the case where the sample stage 7 is continuously driven, if the stage speed v is set as the inspection parameter, the required charge accumulation-waiting time T is set on a one-to-one basis.

Meanwhile, in the case where the sample stage 7 is driven by step & repeat, if the stage speed v is set and further the total time Tₛ is set as the inspection parameters, the required charge accumulation-waiting time T is set on a one-to-one basis.

In the SEM-type visual inspection device 1″ shown in FIG. 14 in which the irradiation site of the electron beam 51 matches the irradiation site of the electron beam 21, if the time T_{bb} from the stopping of the irradiation with the electron beam 51 from the first electron gun 53 until the irradiation with the electron beam 21 for observation from the second electron gun 3 on the observation sample 100 is set as the inspection parameter, the required charge accumulation-waiting time T is set on a one-to-one basis.

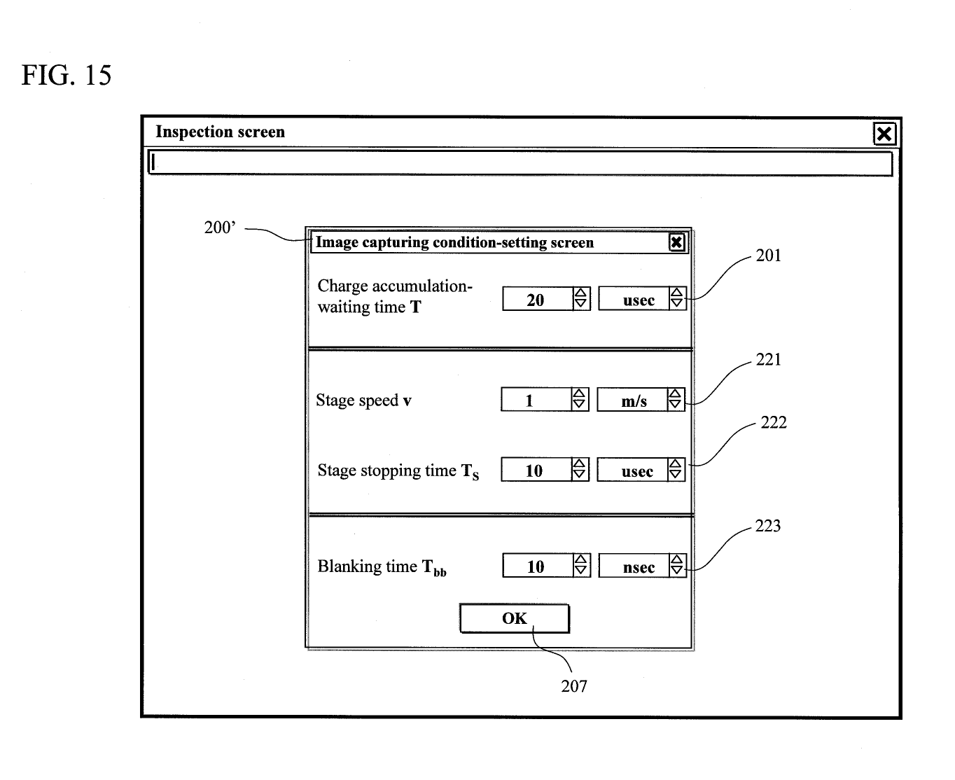

FIG. 15 is a view showing one example of the inspection parameter-input screen as one mode of the input monitor screen in the SEM-type visual inspection device of the present embodiment.

An inspection parameter-input screen (illustrated as an “image capturing condition-setting screen” in FIG. 15) 200′ is displayed in the window on the screen of the monitor 14 through given operation on the input instrument 15 as similarly to the inspection parameter-input screen 200 according to the first embodiment shown in FIG. 7. In the illustrated example, the inspection parameter-input screen 200′ includes: the charge accumulation-waiting time-input column 201 for inputting the charge accumulation-waiting time T; a stage speed-input column 221 for inputting the stage speed v when the sample stage 7 is driven in the case of the SEM-type visual inspection device 1′ in which the irradiation site of the electron beam 51 is different from the irradiation site of the electron beam 21; further a stage stopping time-input column 222 for inputting the total stopping time Tₛ when the sample stage 7 is stopped in the case of driving the sample stage 7 by step & repeat; and also a blanking time-input column 223 for inputting the time T_{bb} from the stopping of the irradiation with the electron beam 51 from the first electron gun 53 until the irradiation with the electron beam 21 for observation from the second electron gun 3 on the observation sample 100 in the case of the SEM-type visual inspection device 1″ in which the irradiation site of the electron beam 51 matches the irradiation site of the electron beam 21.

Further, the inspection parameter-input screen 200′ has the setting button (OK button) 207 for setting input values of these parameters as the inspection parameters of the inspection conditions.

Thus, the operator inputs these inspection parameters T, v, Tₛ, T_{bb} as appropriate depending on the difference in hardware configuration between the SEM-type visual inspection devices 1′, 1″ and also the difference in driving the sample stage 7 in the case of the SEM-type visual inspection device 1′ in which the irradiation site of the electron beam 51 is different from the irradiation site of the electron beam 21.

In this case also, the charge accumulation-waiting time T is inputted at first. Accordingly, depending on the value of the charge accumulation-waiting time T thus inputted, the range of selecting each value of the inspection parameters v, Tₛ, T_{bb} is narrowed. This means less selection choices.

If appropriately inputting the inspection parameters T, v, Tₛ, T_{bb} through the inspection parameter-input screen 200′ as described above, the operator operates the setting button (OK button) 207 to store the inspection parameters T, v, Tₛ, T_{bb} thus inputted through the operation as inspection conditions temporarily in the computer 13 of the SEM-type visual inspection device 1.

Then, the computer 13 of the SEM-type visual inspection device 1 displays, in place of the inspection parameter-input screen 200,′ an inspection starting screen, similar to the inspection starting screen 300 according to the first embodiment shown in FIG. 8, based on the inspection parameters T, v, Tₛ, T_{bb} set through the inspection parameter-input screen 200′ in the window on the screen of the monitor 14.

The operator executes an inspection condition-setting process including a trial inspection, similar to the inspection condition-setting process according to the first embodiment shown in FIG. 9, according to this inspection starting screen, and sets optimum inspection conditions for the main inspection on the basis of the inspection result of the trial inspection.

### Other Embodiments

Hereinabove, the SEM-type visual inspection devices 1, 1′, 1″ have been described as the embodiments of the charged-particle microscope device and the method of controlling charged-particle beams of the present invention. However, the present invention is not restricted to the above-described embodiments, and various changes are possible within the scope of the inventions described in claims. Specifically, the present invention is applicable, other than the SEM-type visual inspection device 1, to, for example, charged-particle microscope devices, such as general electron microscope devices and ion microscopes, which are configured to capture an observation image by detecting an emitted electron emitted from an observation sample by charged-particle beam irradiation.

Furthermore, various modification examples can be made for the specific configuration.

For example, in the description of the setting of inspection parameters according to the inspection parameter-input screens 200, 200′ shown in FIGS. 7 and 15 in the above-described first, second embodiments, the description has been given taking the example of the method in which the operator sets various parameters after the charge accumulation-waiting time T is set. Alternatively, it is possible that various parameters are first set and then the charge accumulation-waiting time T is determined.

Moreover, as to the setting of the charge accumulation-waiting time T, the time may either start from when the initial electron beam irradiation for enhancing charge accumulation is started including the initial electron-beam irradiation time T_{d} per pixel for enhancing charge accumulation, or start from when the initial electron beam irradiation for enhancing charge accumulation is terminated excluding the initial electron-beam irradiation time T_{d} per pixel for enhancing charge accumulation.

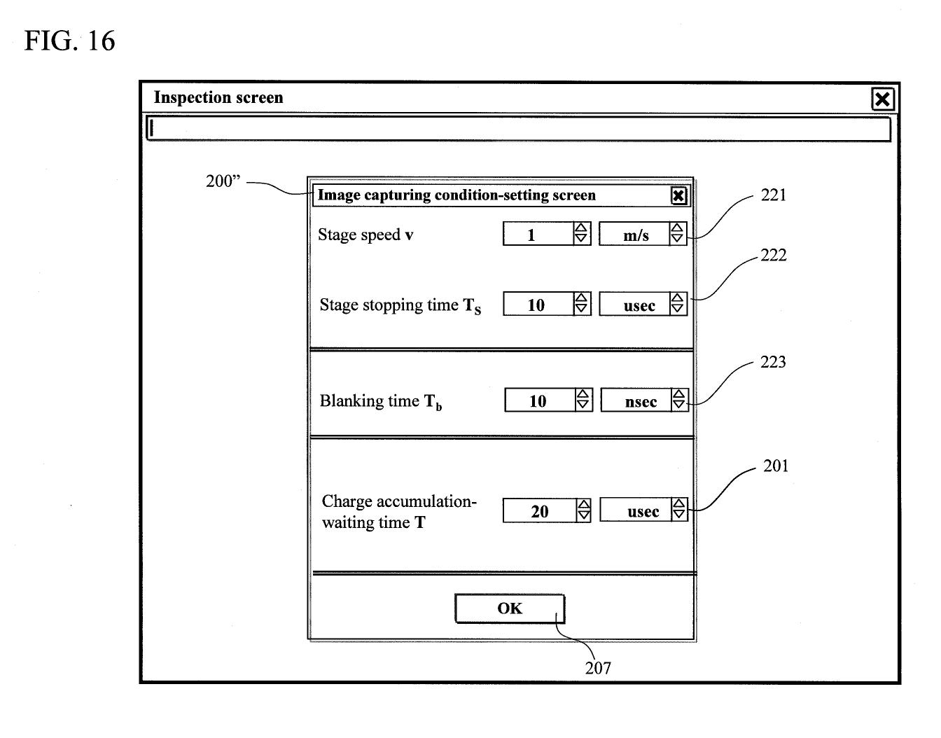

FIG. 16 shows a modification example of the inspection parameter-input screen shown in FIG. 15.

An inspection parameter-input screen 200″ shown in FIG. 16 (illustrated as an “image capturing condition-setting screen” in FIG. 16) urges the operator to first input various parameters v, Tₛ, T_{bb}. By setting the various parameters v, Tₛ, T_{bb}, the charge accumulation-waiting time T is automatically displayed.

Various modification examples can be made even for the operation screens such as the inspection parameter-input screen and the inspection starting screen as described above. Accordingly, it is apparent that modes of carrying out the present invention are not restricted to the aforementioned embodiments, and various changes are possible within the scope of the inventions described in claims.

EXPLANATION OF THE REFERENCE NUMERALS

| | | | |
|---|---|---|---|
| 1, 1′, 1″ SEM-type visual inspection device, | 2 electron source, | 3 electron gun, | 4 deflector, |

| | | | |
|---|---|---|---|
| 5 blanking electrode, | 6 objective lens, | 7 sample stage, | 8 detector, |

| | | | |
|---|---|---|---|
| 9 detection controller, | 10 image processor, | 11 lens controller, | 12 deflection controller, |

| | | | |
|---|---|---|---|
| 13 computer, | 14 monitor, | 15 input instrument, | 21 primary electron beam, |

| | | | |
|---|---|---|---|
| 22 emitted electron, | 51 electron beam, | 52 electron source, | 53 first electron gun, |

| | | |
|---|---|---|
| 55 blanking electrode, | 56 stage-driving control system, | 62 horizontal retrace line, |

| | | |
|---|---|---|
| 64 vertical retrace line, | 100 semiconductor wafer (observation sample), | 101 substrate, |

| | | | |
|---|---|---|---|
| 102 metal film, | 103 insulating film layer, | 104 insulating film portion, | 110 via, |

| | | |
|---|---|---|
| 111 normal portion, | 112 defect portion, | 121 normal portion equivalent circuit, |

| | |
|---|---|
| 122 defect portion equivalent circuit, | 200 inspection parameter-input screen, |

| | |
|---|---|
| 201 charge accumulation-waiting time-input column, | 202 irradiation time-input column, |

| | |
|---|---|
| 203 blanking time-input column, | 204 beam-irradiated pixel-number-input column, |

| | | |
|---|---|---|
| 205 inspected pixel-number-input column, | 206 line-number-input column, | 207 setting button, |

| | |
|---|---|
| 221 stage speed-input column, | 222 stage stopping time-input column, |

| | | |
|---|---|---|
| 223 blanking time-input column, | 300 inspection starting screen, | 300 inspection starting screen, |

| | |
|---|---|
| 310 inspection region-selection window, | 311 wafer map-display section, |

| | | |
|---|---|---|
| 312 wafer map, | 313 inspection region, | 314 region selection key, |

| | |
|---|---|
| 315 cancel key, | 320 trial inspection result-display window, |

| | |
|---|---|
| 330 inspection condition-setting window, | 331 charge accumulation-waiting time-setting column, |

| | |
|---|---|
| 332 irradiation time-setting column, | 333 inspection threshold-setting column, |

| | |
|---|---|
| 334 trial inspection-start button, | 335 trial inspection-stop button, |
| 336 main inspection-start button, | 337 main inspection-stop button, |

| | |
|---|---|
| 340 expected/result-display window, | 341 expected inspection time-display column, |

| | |
|---|---|
| 342 actual inspection time-display column, | 343 defect-number-display column |

1. A charged-particle microscope device using charged-particle beams, the device characterized by comprising:
a charged-particle beam-irradiating unit for irradiating any inspection region of an observation sample held on a stage with charged-particle beams at least twice or more times; and
a setting unit for setting a time lag between an initial charged-particle beam irradiation for enhancing charge accumulation and a next charged-particle beam irradiation for sample observation which are performed by the charged-particle beam-irradiating unit on the observation sample, depending on a state of any one of the observation sample and a defect portion generated on the observation sample.

2. The charged-particle microscope device according to claim 1, characterized in that
the charged-particle beam-irradiating unit includes:
a charged-particle beams-controlling electromagnetic lens; and
a control circuit for operating and controlling the charged-particle beams-controlling electromagnetic lens on the basis of the time lag set by the setting unit.

3. The charged-particle microscope device according to claim 2, characterized in that
on the basis of the time lag set by the setting unit, the control circuit generates a time lag for one irradiation position in an observation region of the observation sample, by making the charged-particle beams-controlling electromagnetic lens perform the initial charged-particle beam irradiation for enhancing charge accumulation on another irradiation position in the observation region between the initial charged-particle beam irradiation for enhancing charge accumulation and the next charged-particle beam irradiation for sample observation which are performed on the one irradiation position.

4. The charged-particle microscope device according to claim 2, characterized in that
the charged-particle beams-controlling electromagnetic lens includes an electromagnetic lens for changing a trajectory of the charged-particle beams in such a manner that the observation sample is not irradiated with the charged-particle beams, and
between the initial charged-particle beam irradiation for enhancing charge accumulation and the next charged-particle beam irradiation for sample observation which are performed on one irradiation position in an observation region of the observation sample, the control circuit operates, on the basis of the time lag set by the setting unit, the electromagnetic lens in accordance with the time lag, and changes the trajectory of the charged-particle beams in such a manner that the observation sample is not irradiated with the charged-particle beams.

5. The charged-particle microscope device according to claim 1, characterized in that the setting unit includes a monitor, and displays an operation screen on a screen of the monitor, the operation screen being for setting or displaying the time lag between the initial charged-particle beam irradiation for enhancing charge accumulation and the next charged-particle beam irradiation for sample observation which are performed on the observation sample.

6. The charged-particle microscope device according to claim 1, characterized in that the charged-particle beam-irradiating unit has at least two or more charged-particle beam generators, and uses the different charged-particle beam generators to respectively perform the initial charged-particle beam irradiation for enhancing charge accumulation and the next charged-particle beam irradiation for sample observation which are on one irradiation position in an observation region of the observation sample.

7. The charged-particle microscope device according to claim 6, characterized in that
the stage includes a stage-driving control system for moving the observation sample between irradiation sites of the different charged-particle beam generators, and
the setting unit sets the time lag between the initial charged-particle beam irradiation for enhancing charge accumulation and the next charged-particle beam irradiation for sample observation which are performed on the observation sample, according to a stage speed of the stage-driving control system.

8. The charged-particle microscope device according to claim 6, characterized in that each of the charged-particle beam generators includes:
a charged-particle beams-controlling electromagnetic lens; and
a control circuit for operating and controlling the charged-particle beams-controlling electromagnetic lens on the basis of the time lag set by the setting unit.

9. The charged-particle microscope device according to claim 6, characterized in that the setting unit includes a monitor, and displays an operation screen on a screen of the monitor, the operation screen being for setting or displaying the time lag between the initial charged-particle beam irradiation for enhancing charge accumulation and the next charged-particle beam irradiation for sample observation which are performed on the observation sample.

10. A charged-particle beam-controlling method of controlling charged-particle beams for irradiating an observation sample, the method characterized by comprising:
a setting step of setting a time lag between an initial charged-particle beam irradiation for enhancing charge accumulation and a next charged-particle beam irradiation for sample observation which are performed on an observation sample, depending on a state of any one of the observation sample and a defect portion generated on the observation sample; and
an irradiation step of performing the initial charged-particle beam irradiation for enhancing charge accumulation and the next charged-particle beam irradiation for sample observation on one irradiation position in an observation region of the observation sample, on the basis of the time lag set in the setting step.

11. The method of controlling charged-particle beams according to claim 10, characterized in that
in the irradiation step, on the basis of the time lag set in the setting step,
the initial charged-particle beam irradiation for enhancing charge accumulation is performed on the one irradiation position in the observation region of the observation sample,
the initial charged-particle beam irradiation for enhancing charge accumulation is performed on another irradiation position in the observation region, and then
the next charged-particle beam irradiation for sample observation is performed on the one irradiation position.

12. The method of controlling charged-particle beams according to claim 10, characterized in that
in the irradiation step, on the basis of the time lag set in the setting step,
the initial charged-particle beam irradiation for enhancing charge accumulation is performed on the one irradiation position in the observation region of the observation sample,
a trajectory of the charged-particle beams is changed in such a manner that the observation sample is not irradiated with the charged-particle beams, and then
the next charged-particle beam irradiation for sample observation is performed on the one irradiation position.

13. The method of controlling charged-particle beams according to claim 10, characterized in that in the irradiation step, the initial charged-particle beam irradiation for enhancing charge accumulation and the next charged-particle beam irradiation for sample observation are performed on the one irradiation position in the observation region of the observation sample by using the different charged-particle beam generators, respectively.
